(19) United States
(12) Patent Application Publication
(10) Pub. No.: US 2012/0149193 A1
(43) Pub. Date: Jun. 14, 2012

(54) METHOD FOR MANUFACTURING A SEMICONDUCTOR MEMORY DEVICE

(75) Inventor: Naonori FUJIWARA, Tokyo (JP)

(73) Assignee: ELPIDA MEMORY, INC., Tokyo (JP)

(21) Appl. No.: 13/311,838

(22) Filed: Dec. 6, 2011

(30) Foreign Application Priority Data
Dec. 8, 2010 (JP) 2010-273749

(51) Int. Cl. H01L 21/28; H01L 21/316

(52) U.S. Cl. 438/675; 438/763; 257/E21.28; 257/E21.158

(57) ABSTRACT

A method for forming a semiconductor device includes the following processes. An insulating film is formed over a semiconductor substrate. A hole is formed in the insulating film. A film including ZrAlO is formed over the insulating film and in the hole. Forming the film including ZrAlO may include, but is not limited to, the following processes. A first precursor including zirconium and a second precursor including aluminum are supplied into a reaction chamber at a supply amount ratio of the first precursor to the second precursor in the range from 2.5 to 3.5. The first precursor and the second precursor are exhausted from the reaction chamber. An oxidant is supplied into the reaction chamber to oxidize zirconium and aluminum. The oxidant is exhausted from the reaction chamber.

### BACKGROUND OF THE INVENTION

1. Field of the Invention

The present invention generally relates to a method for manufacturing a semiconductor memory device.

Priority is claimed on Japanese Patent Application No. 2010-273749, filed Dec. 8, 2010, the content of which is incorporated herein by reference.

2. Description of the Related Art

In recent years, with the shrinking of the cell size in DRAMs (dynamic random access memories), the gate lengths of cell array access transistors (hereinafter referred to as cell transistors) have also been shortened. However, the shorter the gate length becomes, the more prominent the short-channel effect of the transistor becomes, and there is a tendency for the sub-threshold current to increase and a threshold voltage (Vth) of the transistor to decrease. As a method of countering this, there is a method of increasing a concentration of impurity elements in a substrate to suppress the decrease of the threshold voltage. However, the refresh characteristics of the DRAM are deteriorated because the junction leakage increases.

To avoid such phenomenon, Japanese Unexamined Patent Applications, First Publication, Nos. JP-A-2006-339476 and JP-A-2007-081095 disclose a so-called trench gate transistor (also known as a recessed-channel transistor) in which part of a gate electrode is buried into a trench in a silicon substrate has been adopted. With the trench gate transistor, it is possible to physically and sufficiently establish the effective channel length (gate length). It is possible to achieve a microfine DRAM having a minimum process dimension of 60 nm or smaller.

### SUMMARY

In one embodiment, a method for forming a semiconductor device may include, but is not limited to, the following processes. An insulating film is formed over a semiconductor substrate. A hole is formed in the insulating film. A film including ZrAlO is formed over the insulating film and in the hole. Forming the film including ZrAlO may include, but is not limited to, the following processes. A first precursor including zirconium and a second precursor including aluminum are supplied into a reaction chamber at a supply amount ratio of the first precursor to the second precursor in the range from 2.5 to 3.5. The first precursor and the second precursor are exhausted from the reaction chamber. An oxidant is supplied into the reaction chamber to oxidize zirconium and aluminum. The oxidant is exhausted from the reaction chamber.

In another embodiment, a method for forming a semiconductor device may include, but is not limited to, the following processes. An insulating film is formed over a semiconductor substrate. A hole is formed in the insulating film. A conductive film is formed over the insulating film and in the hole. A film including ZrAlO is formed over the conductive film by atomic layer deposition. Forming the film including ZrAlO may include, but is not limited to, the following processes. A first precursor including zirconium and a second precursor including aluminum are supplied into a reaction chamber to form a mono-molecular layer so that a first molecular ratio of the first precursor in the mono-molecular layer at a bottom of the hole is substantially the same as a second molecular ratio of the first precursor in the mono-molecular layer over a top surface of the insulating film. The first precursor and the second precursor are exhausted from the reaction chamber. An oxidant is supplied to the reaction chamber to oxidize zirconium and aluminum. The oxidant is exhausted from the reaction chamber.

In still another embodiment, a method for forming a semiconductor device may include, but is not limited to, the following processes. An insulating film is formed over a semiconductor substrate. A hole is formed in the insulating film. A first electrode is formed in the hole. A capacitive insulating film including ZrAlO is formed over the conductive film and the insulating film. A second electrode is formed over the capacitive insulating film. Forming the capacitive insulating film may include, but is not limited to, the following processes. A first precursor including zirconium and a second precursor including aluminum are supplied into a reaction chamber at a supply amount ratio of the first precursor to the second precursor in the range from 2.5 to 3.5. The first precursor and the second precursor are exhausted from the reaction chamber. An oxidant is supplied into the reaction chamber to oxidize zirconium and aluminum. The oxidant is exhausted from the reaction chamber.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary plan view illustrating a semiconductor device including a memory cell provided with a semiconductor memory device in accordance with a first preferred embodiment of the present invention;

FIG. 2A is a fragmentary cross sectional elevation view, taken along with an A-A′ line of FIG. 1, illustrating the semiconductor device including the memory cell in accordance with the first preferred embodiment of the present invention;

FIG. 2B is a fragmentary cross sectional elevation view, taken along with a B-B′ line of FIG. 1, illustrating the semiconductor device including the memory cell in accordance with the first preferred embodiment of the present invention;

FIG. 3A is a fragmentary cross sectional elevation view, taken along with the A-A′ line of FIG. 1, illustrating the semiconductor device in a step involved in a method of forming the semiconductor device of FIG. 1 in accordance with a first preferred embodiment of the present invention;

FIG. 3B is a fragmentary cross sectional elevation view, taken along with the B-B′ line of FIG. 1, illustrating the semiconductor device in a step involved in the method of forming the semiconductor device of FIG. 1 in accordance with a first preferred embodiment of the present invention;

FIG. 4A is a fragmentary cross sectional elevation view, taken along with the A-A′ line of FIG. 1, illustrating the semiconductor device in a step, subsequent to FIG. 3A, involved in the method of forming the semiconductor device of FIG. 1 in accordance with a first preferred embodiment of the present invention;

FIG. 4B is a fragmentary cross sectional elevation view, taken along with the B-B′ line of FIG. 1, illustrating the semiconductor device in a step, subsequent to FIG. 3B, involved in the method of forming the semiconductor device of FIG. 1 in accordance with a first preferred embodiment of the present invention;

FIG. 5A is a fragmentary cross sectional elevation view, taken along with the A-A′ line of FIG. 1, illustrating the semiconductor device in a step, subsequent to FIG. 4A, involved in the method of forming the semiconductor device of FIG. 1 in accordance with a first preferred embodiment of the present invention;

FIG. 5B is a fragmentary cross sectional elevation view, taken along with the B-B′ line of FIG. 1, illustrating the semiconductor device in a step, subsequent to FIG. 5B, involved in the method of forming the semiconductor device of FIG. 1 in accordance with a first preferred embodiment of the present invention;

FIG. 6A is a fragmentary cross sectional elevation view, taken along with the A-A′ line of FIG. 1, illustrating the semiconductor device in a step, subsequent to FIG. 5A, involved in the method of forming the semiconductor device of FIG. 1 in accordance with a first preferred embodiment of the present invention;

FIG. 6B is a fragmentary cross sectional elevation view, taken along with the B-B′ line of FIG. 1, illustrating the semiconductor device in a step, subsequent to FIG. 5B, involved in the method of forming the semiconductor device of FIG. 1 in accordance with a first preferred embodiment of the present invention;

FIG. 7A is a fragmentary cross sectional elevation view, taken along with the A-A′ line of FIG. 1, illustrating the semiconductor device in a step, subsequent to FIG. 6A, involved in the method of forming the semiconductor device of FIG. 1 in accordance with a first preferred embodiment of the present invention;

FIG. 7B is a fragmentary cross sectional elevation view, taken along with the B-B′ line of FIG. 1, illustrating the semiconductor device in a step, subsequent to FIG. 6B, involved in the method of forming the semiconductor device of FIG. 1 in accordance with a first preferred embodiment of the present invention;

FIG. 8A is a fragmentary cross sectional elevation view, taken along with the A-A′ line of FIG. 1, illustrating the semiconductor device in a step, subsequent to FIG. 7A, involved in the method of forming the semiconductor device of FIG. 1 in accordance with a first preferred embodiment of the present invention;

FIG. 8B is a fragmentary cross sectional elevation view, taken along with the B-B′ line of FIG. 1, illustrating the semiconductor device in a step, subsequent to FIG. 7B, involved in the method of forming the semiconductor device of FIG. 1 in accordance with a first preferred embodiment of the present invention;

FIG. 9A is a fragmentary cross sectional elevation view, taken along with the A-A′ line of FIG. 1, illustrating the semiconductor device in a step, subsequent to FIG. 8A, involved in the method of forming the semiconductor device of FIG. 1 in accordance with a first preferred embodiment of the present invention;

FIG. 9B is a fragmentary cross sectional elevation view, taken along with the B-B′ line of FIG. 1, illustrating the semiconductor device in a step, subsequent to FIG. 8B, involved in the method of forming the semiconductor device of FIG. 1 in accordance with a first preferred embodiment of the present invention;

FIG. 10A is a fragmentary cross sectional elevation view, taken along with the A-A′ line of FIG. 1, illustrating the semiconductor device in a step, subsequent to FIG. 9A, involved in the method of forming the semiconductor device of FIG. 1 in accordance with a first preferred embodiment of the present invention;

FIG. 10B is a fragmentary cross sectional elevation view, taken along with the B-B′ line of FIG. 1, illustrating the semiconductor device in a step, subsequent to FIG. 9B, involved in the method of forming the semiconductor device of FIG. 1 in accordance with a first preferred embodiment of the present invention;

FIG. 11A is a fragmentary cross sectional elevation view, taken along with the A-A′ line of FIG. 1, illustrating the semiconductor device in a step, subsequent to FIG. 10A, involved in the method of forming the semiconductor device of FIG. 1 in accordance with a first preferred embodiment of the present invention;

FIG. 11B is a fragmentary cross sectional elevation view, taken along with the B-B′ line of FIG. 1, illustrating the semiconductor device in a step, subsequent to FIG. 10B, involved in the method of forming the semiconductor device of FIG. 1 in accordance with a first preferred embodiment of the present invention;

FIG. 12A is a fragmentary cross sectional elevation view, taken along with the A-A′ line of FIG. 1, illustrating the semiconductor device in a step, subsequent to FIG. 11A, involved in the method of forming the semiconductor device of FIG. 1 in accordance with a first preferred embodiment of the present invention;

FIG. 12B is a fragmentary cross sectional elevation view, taken along with the B-B′ line of FIG. 1, illustrating the semiconductor device in a step, subsequent to FIG. 11B, involved in the method of forming the semiconductor device of FIG. 1 in accordance with a first preferred embodiment of the present invention;

FIG. 13A is a fragmentary cross sectional elevation view, taken along with the A-A′ line of FIG. 1, illustrating the semiconductor device in a step, subsequent to FIG. 12A, involved in the method of forming the semiconductor device of FIG. 1 in accordance with a first preferred embodiment of the present invention;

FIG. 13B is a fragmentary cross sectional elevation view, taken along with the B-B′ line of FIG. 1, illustrating the semiconductor device in a step, subsequent to FIG. 12B, involved in the method of forming the semiconductor device of FIG. 1 in accordance with a first preferred embodiment of the present invention;

FIG. 14A is a fragmentary cross sectional elevation view, taken along with the A-A′ line of FIG. 1, illustrating the semiconductor device in a step, subsequent to FIG. 13A, involved in the method of forming the semiconductor device of FIG. 1 in accordance with a first preferred embodiment of the present invention;

FIG. 14B is a fragmentary cross sectional elevation view, taken along with the B-B′ line of FIG. 1, illustrating the semiconductor device in a step, subsequent to FIG. 13B, involved in the method of forming the semiconductor device of FIG. 1 in accordance with a first preferred embodiment of the present invention;

FIG. 15A is a fragmentary cross sectional elevation view, taken along with the A-A′ line of FIG. 1, illustrating the semiconductor device in a step, subsequent to FIG. 14A, involved in the method of forming the semiconductor device of FIG. 1 in accordance with a first preferred embodiment of the present invention;

FIG. 15B is a fragmentary cross sectional elevation view, taken along with the B-B′ line of FIG. 1, illustrating the semiconductor device in a step, subsequent to FIG. 14B, involved in the method of forming the semiconductor device of FIG. 1 in accordance with a first preferred embodiment of the present invention;

FIG. 16A is a fragmentary cross sectional elevation view, taken along with the A-A′ line of FIG. 1, illustrating the semiconductor device in a step, subsequent to FIG. 15A, involved in the method of forming the semiconductor device of FIG. 1 in accordance with a first preferred embodiment of the present invention;

FIG. 16B is a fragmentary cross sectional elevation view, taken along with the B-B′ line of FIG. 1, illustrating the semiconductor device in a step, subsequent to FIG. 15B, involved in the method of forming the semiconductor device of FIG. 1 in accordance with a first preferred embodiment of the present invention;

FIG. 17A is a fragmentary cross sectional elevation view, taken along with the A-A′ line of FIG. 1, illustrating the semiconductor device in a step, subsequent to FIG. 16A, involved in the method of forming the semiconductor device of FIG. 1 in accordance with a first preferred embodiment of the present invention;

FIG. 17B is a fragmentary cross sectional elevation view, taken along with the B-B′ line of FIG. 1, illustrating the semiconductor device in a step, subsequent to FIG. 16B, involved in the method of forming the semiconductor device of FIG. 1 in accordance with a first preferred embodiment of the present invention;

FIG. 18A is a fragmentary cross sectional elevation view, taken along with the A-A′ line of FIG. 1, illustrating the semiconductor device in a step, subsequent to FIG. 17A, involved in the method of forming the semiconductor device of FIG. 1 in accordance with a first preferred embodiment of the present invention;

FIG. 18B is a fragmentary cross sectional elevation view, taken along with the B-B′ line of FIG. 1, illustrating the semiconductor device in a step, subsequent to FIG. 17B, involved in the method of forming the semiconductor device of FIG. 1 in accordance with a first preferred embodiment of the present invention;

FIG. 19A is a fragmentary cross sectional elevation view, taken along with the A-A′ line of FIG. 1, illustrating the semiconductor device in a step, subsequent to FIG. 18A, involved in the method of forming the semiconductor device of FIG. 1 in accordance with a first preferred embodiment of the present invention;

FIG. 19B is a fragmentary cross sectional elevation view, taken along with the B-B′ line of FIG. 1, illustrating the semiconductor device in a step, subsequent to FIG. 18B, involved in the method of forming the semiconductor device of FIG. 1 in accordance with a first preferred embodiment of the present invention;

FIG. 20A is a fragmentary cross sectional elevation view, taken along with the A-A′ line of FIG. 1, illustrating the semiconductor device in a step, subsequent to FIG. 19A, involved in the method of forming the semiconductor device of FIG. 1 in accordance with a first preferred embodiment of the present invention;

FIG. 20B is a fragmentary cross sectional elevation view, taken along with the B-B′ line of FIG. 1, illustrating the semiconductor device in a step, subsequent to FIG. 19B, involved in the method of forming the semiconductor device of FIG. 1 in accordance with a first preferred embodiment of the present invention;

FIG. 21A is a fragmentary cross sectional elevation view, taken along with the A-A′ line of FIG. 1, illustrating the semiconductor device in a step, subsequent to FIG. 20A, involved in the method of forming the semiconductor device of FIG. 1 in accordance with a first preferred embodiment of the present invention;

FIG. 21B is a fragmentary cross sectional elevation view, taken along with the B-B′ line of FIG. 1, illustrating the semiconductor device in a step, subsequent to FIG. 20B, involved in the method of forming the semiconductor device of FIG. 1 in accordance with a first preferred embodiment of the present invention;

FIG. 22A is a fragmentary cross sectional elevation view, taken along with the A-A′ line of FIG. 1, illustrating the semiconductor device in a step, subsequent to FIG. 21A, involved in the method of forming the semiconductor device of FIG. 1 in accordance with a first preferred embodiment of the present invention;

FIG. 22B is a fragmentary cross sectional elevation view, taken along with the B-B′ line of FIG. 1, illustrating the semiconductor device in a step, subsequent to FIG. 21B, involved in the method of forming the semiconductor device of FIG. 1 in accordance with a first preferred embodiment of the present invention;

FIG. 23A is a fragmentary cross sectional elevation view, taken along with the A-A′ line of FIG. 1, illustrating the semiconductor device in a step, subsequent to FIG. 22A, involved in the method of forming the semiconductor device of FIG. 1 in accordance with a first preferred embodiment of the present invention;

FIG. 23B is a fragmentary cross sectional elevation view, taken along with the B-B′ line of FIG. 1, illustrating the semiconductor device in a step, subsequent to FIG. 22B, involved in the method of forming the semiconductor device of FIG. 1 in accordance with a first preferred embodiment of the present invention;

FIG. 24A is a fragmentary cross sectional elevation view, taken along with the A-A′ line of FIG. 1, illustrating the semiconductor device in a step, subsequent to FIG. 23A, involved in the method of forming the semiconductor device of FIG. 1 in accordance with a first preferred embodiment of the present invention;

FIG. 24B is a fragmentary cross sectional elevation view, taken along with the B-B′ line of FIG. 1, illustrating the semiconductor device in a step, subsequent to FIG. 23B, involved in the method of forming the semiconductor device of FIG. 1 in accordance with a first preferred embodiment of the present invention;

FIG. 25 is a fragmentary plan view illustrating the semiconductor device including the memory cell provided with the semiconductor memory device in accordance with the first preferred embodiment of the present invention;

FIG. 26A is a fragmentary cross sectional elevation view, at a position equivalent to the position along the line A-A′ of FIG. 1, illustrating a semiconductor device including a memory cell in accordance with a second preferred embodiment of the present invention;

FIG. 26B is a fragmentary cross sectional elevation view, at a position equivalent to the position along the line B-B′ of FIG. 1, illustrating the semiconductor device including the memory cell in accordance with the second preferred embodiment of the present invention;

FIG. 27A is a fragmentary cross sectional elevation view illustrating the semiconductor device in a step involved in a method of forming the semiconductor device of FIGS. 26A and 26B in accordance with the second preferred embodiment of the present invention;

FIG. 27B is a fragmentary cross sectional elevation view illustrating the semiconductor device in a step involved in the method of forming the semiconductor device of FIGS. 26A and 26B in accordance with the second preferred embodiment of the present invention;

FIG. 28A is a fragmentary cross sectional elevation view illustrating the semiconductor device in a step, subsequent to FIG. 27A, involved in the method of forming the semiconductor device of FIGS. 26A and 26B in accordance with the second preferred embodiment of the present invention;

FIG. 28B is a fragmentary cross sectional elevation view illustrating the semiconductor device in a step, subsequent to FIG. 27B, involved in the method of forming the semiconductor device of FIGS. 26A and 26B in accordance with the second preferred embodiment of the present invention;

FIG. 29A is a graph showing a relationship between a precursor supplying time and a covering ratio of the precursors (TMA and TEMAZ) in accordance with the first preferred embodiment of the present invention;

FIG. 29B is a schematic diagram illustrating showing a condition of TMA and TEMAZ adsorption within a deep hole formed in a semiconductor substrate surface, in accordance with the first preferred embodiment of the present invention;

FIG. 30A is a gas flow sequence in the case where TMA and TEMAZ are supplied in the same step in accordance with the first preferred embodiment of the present invention;

FIG. 30B is a gas flow sequence in the case where TMA and TEMAZ are supplied in the different timing in accordance with the first preferred embodiment of the present invention;

FIG. 31 is a graph showing a relationship between a depth of the deep hole and a zirconium/aluminum ratio in an ALD film formed by the method in accordance with the first preferred embodiment of the present invention;

FIG. 32 is a gas flow sequence in the case where supplying time of TMA are different from that of TEMAZ in accordance with the first preferred embodiment of the present invention;

FIG. 33 is a fragmentary cross sectional elevation illustrating a semiconductor device including a memory cell provided with a semiconductor memory device in accordance with the related art;

FIG. 34A is a flow chart showing a deposition method in accordance with the related art;

FIG. 34B is a gas flow sequence of TMA, TEMAZ and O₃ in accordance with the related art;

FIG. 35 is a flow chart showing a deposition method in accordance with the related art;

FIG. 36 is a graph showing a relationship between a depth of the deep hole and a zirconium/aluminum ratio in an ALD film formed by the method in accordance with the related art;

FIG. 37A is a graph showing a relationship between a precursor supplying time and a covering ratio of the precursors (TMA and TEMAZ) in accordance with the related art; and

FIG. 37B is a schematic diagram illustrating showing a condition of TMA and TEMAZ adsorption within a deep hole formed in a semiconductor substrate surface, in accordance with the related art.

### DETAILED DESCRIPTION OF THE PREFERRED EMBODIMENTS

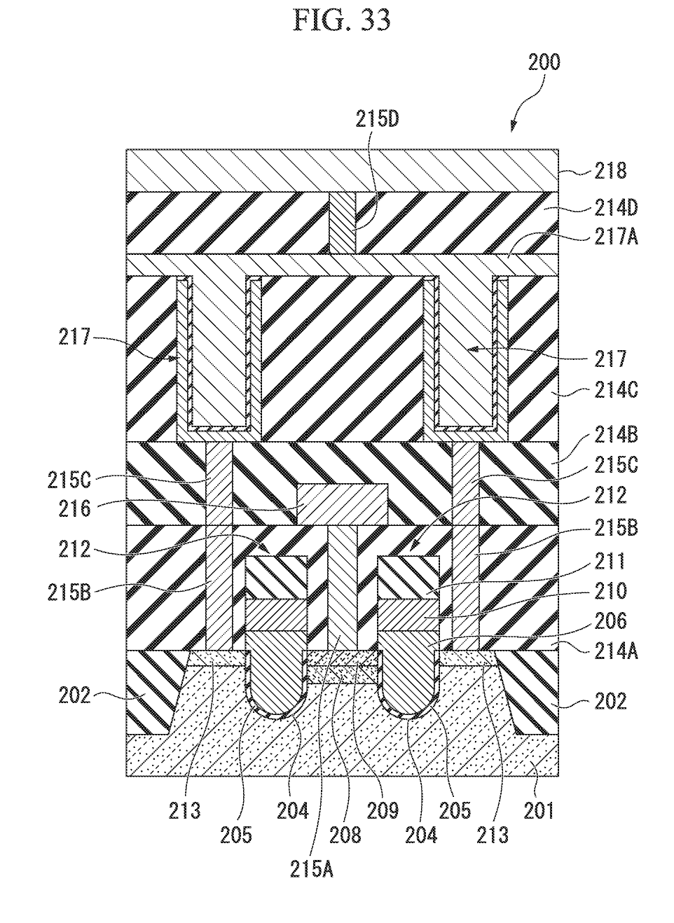

Before describing the present invention, the related art will be explained in detail with reference to FIGS. 33 to 37B, in order to facilitate the understanding of the present invention.

FIG. 33 is a cross-sectional view showing in simplified form an example of the structure of a DRAM having the above-noted trench gate cell transistor. A DRAM 200 having the structure shown in FIG. 33, includes element separation regions 202 which are formed so as to be separated from one another on a surface region of a p-type silicon substrate 201. A plurality of gate trenches 204 are formed so as to be separated from one another left-to-right as shown in FIG. 33 in a region of the semiconductor substrate 201 that is sandwiched between element separation regions 202. A gate electrode 212 is formed so as to bury the gate trench 204. On the inner wall surface of the gate trench 204, a gate insulating film 205 is formed. The gate insulating film 205 is interposed between the inner wall surface of the gate trench 204 and the gate electrode 212.

The gate electrode 212 buries the gate trench 204 and also is formed so as to protrude from the surface of the silicon substrate 201. The gate electrode 212 in this case has a three-layer structure made of, from the bottom, a polysilicon film 206, a high melting point metal film 210, and a gate capacitive insulating film 211. The part that protrudes from the gate trench 204 is covered by a first interlayer insulating film 214A.

A high-concentration n-type diffusion layer 209 is formed in the surface part of the silicon substrate 201 which is sandwiched between the gate electrodes 212 as shown in FIG. 33. A low-concentration n-type diffusion layer 208 is positioned below the high-concentration n-type diffusion layer 209. A low-concentration n-type diffusion layer 213 is formed on the outside of the surface part of the silicon substrate 201 which is sandwiched between the gate electrodes 212. A contact plug (bit interconnect contact) 215A is formed in a first opening formed in the first interlayer insulating film 214A. The first opening is positioned above the high-concentration n-type diffusion layer 209. The contact plug 215A electrically connects the high-concentration n-type diffusion layer 209 and a bit wiring 216 which is positioned over the contact plug 215A. A contact plug 215B is formed in a second opening formed in the interlayer insulating film 214A. The second opening is positioned above the low-concentration n-type diffusion layer 213. The contact plug 215B electrically connects the low-concentration n-type diffusion layer 213 and a contact plug 215C which is positioned over the contact plug 215B.

A second interlayer insulating film 214B is formed above the first interlayer insulating film 214A. The bit wiring 216 is formed above the contact plug 215A in the second interlayer insulating film 214B. The second contact plug 215C is formed in a third opening in the second interlayer insulating film 214B. The third opening is positioned above the contact plug 215B. The second contact plug 215C electrically connects the contact plug 215B and a cell capacitor 217.

A third interlayer insulating film 214C is formed above the second interlayer insulating film 214B. A cell capacitor 217 is formed in a fourth opening in the third interlayer insulating film 214C so as to be electrically coupled to the second contact plug 215C. A fourth interlayer insulating film 214D is formed over an upper electrode 217A of the cell capacitor 217. The upper electrode 217A of the cell capacitor 217 and a wiring 218 are electrically connected via a third contact plug 215D formed in a fifth opening in the fourth interlayer insulating film 214D. The above forms the DRAM 200 having the general structure shown in FIG. 33.

In the DRAM 200 having the structure shown as an example in FIG. 33, with the shrinking of sizes in semiconductor memory devices, because of the reduction in the plan view dimensions of the cell capacitor 217, it has become difficult to achieve a capacitance of the cell capacitor 217 that is required to maintain DRAM operation. A countermeasure that is envisioned is that of forming the third interlayer insulating film 214C in which the cell capacitor 217 is formed thicker and making a cylinder hole in which the cell capacitor 217 is formed deeper, so as to expand the surface area of the cell capacitor 217. However, the formation of the deeper cylinder hole is difficult. Therefore, one of remaining countermeasures is to adopt a capacitive insulating film having a high dielectric constant. In order to form such a capacitive insulating film inside a deep hole, good step coverage is required. To meet this requirement, it is preferable to use ALD (atomic layer deposition) for formation.

For example, in forming a dielectric oxide film by ALD, a mono-molecular layer of dielectric oxide is formed by the four steps of (1) supplying a raw material (precursor) into a reaction chamber in which the semiconductor substrate is placed, (2) exhausting the precursor, (3) supplying an oxidant, and (4) exhausting the oxidant. With the above-noted four steps as one cycle, the cycle is repeated until reaching the desired thickness so as to form the dielectric oxide film. The precursor that is supplied in the above-noted precursor supplying step is adsorbed at the adsorption sites on the semiconductor substrate surface. When all of the adsorption sites of the semiconductor substrate surface have been covered and placed in the saturated condition by the precursor, no further precursor adsorption occurs, and the condition in which a mono-atomic layer of the precursor has been adsorbed is achieved. Next, in the precursor exhausting step, in order to avoid a gas-phase reaction between the precursor that remains in the reaction chamber and the oxidant that is supplied in the later step, the precursor remaining in the reaction chamber is exhausted. Next, in the oxidant supplying step, an oxidant such as, for example, ozone, is supplied, and the already adsorbed mono-atomic layer of precursor is oxidized, so as to form a mono-molecular layer of an oxide-derivative dielectric. Additionally, to avoid a gas-phase reaction with the precursor that is supplied for the next cycle, the oxidant exhausting step is performed.

In ALD, by utilizing the auto-inhibition mechanism of the surface reaction by adsorption, it is possible to perform the control for each mono-atomic layer (or mono-molecular layer). Because of this, the ALD method is superior in terms of film thickness uniformity, film thickness controllability, and step coverage.

As used herein, the term step coverage refers to an index that indicates, when forming a film over the surface of a member having a step, the uniformity of the film thickness from the upper surface of the step down to the bottom part of the step. It is usually expressed as a percentage of the ratio of the minimum thickness of the film formed at the bottom part of the step with respect to the maximum thickness of the film formed at the upper surface of the step. Therefore, if there is coverage with a uniform film thickness form the upper surface to the bottom part of the step, the step coverage is 100%.

In recent years, in order to achieve a capacitive insulating film having a high dielectric constant, a capacitive insulating film that has a laminated structure or a hybrid structure made of different metal compound materials have been used. In this case, a capacitive insulating film that includes at least two types of metal elements is formed by ALD, the method used being either of the following two described methods.

Japanese Unexamined Patent Applications, First Publication, Nos. JP-A-2004-214304, JP-A-2007-150242, and JP-A-2008-244428 disclose a film forming method in which the precursor that is supplied is changed for the molecular layer formed in each one cycle. Specifically, a method is described as follows. After forming a mono-molecular layer as first ALD film that includes a first metal material, a mono-molecular layer as a second ALD film that includes a second metal material is formed. The formation of the first ALD film and the formation of the second ALD film are alternately repeated plurality of times to form a capacitive insulating film having a laminated structure. In this case, there is no restriction to a mono-molecular layer as the first and second ALD films, and lamination can be done alternately a plurality of molecular layers at a time for each of the formations of the first and second films.

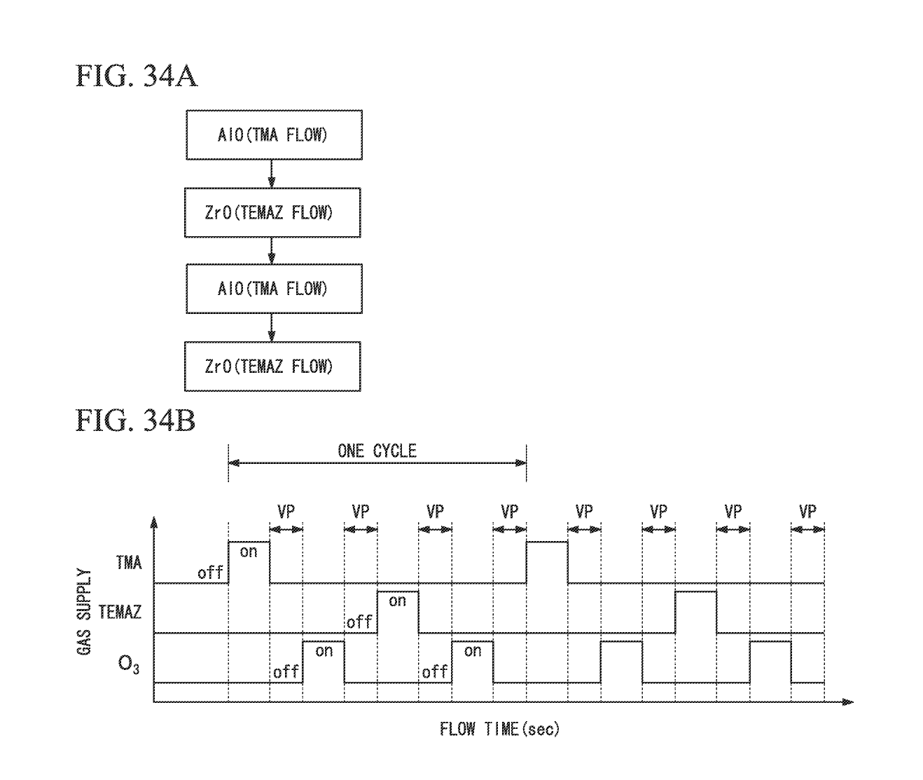

One example of the first method is shown in FIG. 34A. For example, the case of forming a ZrAlO film made of a lamination of aluminum oxide (AlO) and zirconium oxide (ZrO) by using ALD will be described. After a TMA (trimethylaluminum) flow step in which a mono-molecular layer of AlO is formed, a TEMAZ (tetrakis(ethylmethylamino)zirconium) flow step is done to form a mono-molecular layer of ZrO over the AlO, and these being repeated. More specifically, as shown in FIG. 34B, one cycle including steps of supplying TMA that serves as the aluminum precursor, exhausting TMA, supplying ozone (O₃) that serves as the oxidant, exhausting ozone, supplying TEMAZ that serves as the zirconium precursor, exhausting the TEMAZ, supplying ozone, and exhausting ozone is repeated to form the ZrAlO film.

According to this method, it is possible to form a film by alternate laminations of AlO and ZrO for each molecule.

In the case of the methods shown in FIG. 34A and FIG. 34B, however, the ratio of concentrations of zirconium and aluminum in the ZrAlO film cannot be continuously controlled, because the ratio of concentrations of zirconium and aluminum is controlled by the number of the AlO film formation and the ZrO film formation. Also, with the method shown in FIG. 34B, it is difficult to make the concentration of only one of the metal materials extremely low.

For example, whereas the film thickness of one layer of each layer than can be formed by this method is approximately 0.1 nm, a capacitive insulating film is usually formed to a thickness of several nanometers. For this reason, if the concentration ratio of zirconium to aluminum is 95/5, for example, so that one of the concentrations is extremely low, with respect to the overall ZrAlO film, it is only possible to form a film of AlO that is one layer or so, making it difficult to control the concentrations of zirconium and aluminum. Also, the productivity may be considerably reduced with this method.

As another example, Published Japanese Translation of PCT application No. JP-T 2008-502805 discloses a method including a step of supplying two or more types of precursors into the reaction chamber simultaneously.

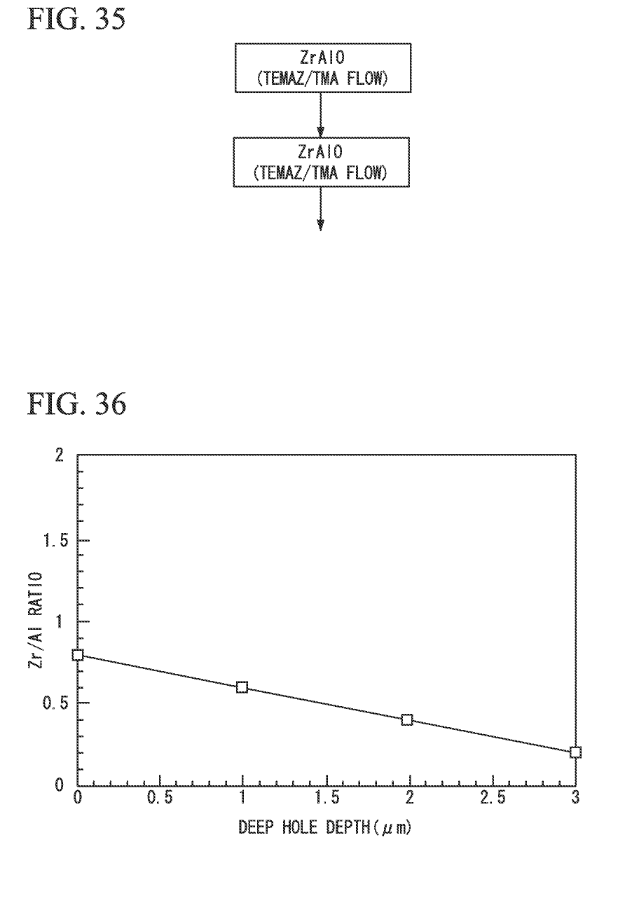

A specific example of the second method is shown in FIG. 35. For example, in the case of forming a ZrAlO film, a cycle including the steps of supplying simultaneously an aluminum precursor and a zirconium precursor, exhausting the aluminum precursor and the zirconium precursor, supplying an oxidant, and exhausting the oxidant is repeated. According to this method, because the aluminum precursor and the zirconium precursor are simultaneously supplied, continuous control is supposed to be possible of the zirconium and aluminum concentrations by controlling the flow amounts of each precursor. For this reason, it is thought that it is possible to make the concentration of only one of the metals extremely low.

Using the method of FIG. 35, however, if the above-noted ALD method is actually used to form the ZrAlO film over a member having a deep hole, the atom count ratio (zirconium/aluminum ratio) between zirconium and aluminum in the ZrAlO film differs depending upon the position in the deep hole depth direction.

FIG. 36 shows the result of an example of experiment performed by the inventor. A silicon substrate having a plurality of deep holes with a depth of 3 μm and a diameter of 150 nm was prepared. The silicon substrate was placed in a reaction chamber. TMA as the aluminum precursor and TEMAZ as the zirconium precursor were supplied to the reaction chamber at the same flow amount to form a ZrAlO film. The zirconium/aluminum ratio of the formed ZrAlO film in the depth direction of the deep hole was investigated.

The silicon substrate was divided after formation of the ZrAlO film and the cross-section of the deep hole exposed. The zirconium/aluminum ratio shown in FIG. 36 was calculated by using the number of atoms of each element obtained analyzing by a transmission electron microscope (TEM)-EDX (energy dispersive X-ray spectroscopy) with respect to the ZrAlO film formed within the deep hole.

As shown in FIG. 36 there is a difference in the zirconium/aluminum ratio between the upper part and the bottom part within the trench. Whereas at the upper part of the deep hole, that is, at the position of the silicon substrate surface, at which the depth is zero, the zirconium/aluminum ratio is 0.8, the zirconium/aluminum ratio at a depth of 3 μm, which is the bottom part of the deep hole, is 0.2. This result indicates that there is a reduction in the zirconium concentration going from the surface to the bottom part of the deep hole.

A ZrAlO film having a zirconium/aluminum ratio that varies depending upon the position in the deep hole as noted above has the leakage current characteristics and dielectric constant differing depending upon the position in the deep hole. Therefore, such a ZrAlO film is difficult to be applied to a capacitive insulating film in a semiconductor memory device, in which stable reliably is required.

Therefore, even with the ALD method that supplies the aluminum precursor and the zirconium precursor in the same step to form the ZrAlO film within the deep hole, there is a need for a method of forming a ZrAlO film having a constant zirconium/aluminum ratio, regardless of the position in the deep hole.

One aspect of one embodiment of the present invention is to provide, in a method of forming a ZrAlO film by ALD in which TMA as an aluminum precursor and TEMAZ as a zirconium precursor are supplied in the same step, a method of forming the ZrAlO film in which a difference in the zirconium/aluminum ratio within the ZrAlO film does not occur depending upon the position within a deep hole formed in a silicon substrate, the zirconium/aluminum ratio being substantially constant at any position.

Another aspect one embodiment of the present invention is to provide a method for forming a semiconductor memory device including a capacitor that uses the above-noted ZrAlO film as a capacitive insulating film.

The inventor, as shown in FIG. 36, performed various experimental investigations to search for the cause of a difference in the zirconium/aluminum ratio of the ZrAlO film that is dependent upon the position within the deep hole. As a result, it was learned that, TMA as an aluminum precursor and TEMAZ as a zirconium precursor have different dependency on the supplying time of each precursors with respect to the coverage ratio.

In this case, the covering ratio is an index that indicates the degree of the proportion to which the precursors are adsorbed and cover a substrate surface with respect to the overall adsorption sites on the substrate surface. For example, TMA is supplied for 200 seconds, which is a time sufficiently longer than the time to completely cover all of the adsorption sites on the substrate surface. The number of aluminum atoms adsorbed into the substrate surface in this case is determined by the above-described EDX. The number of aluminum atoms at this time is taken as the aluminum saturation atom count. After that, samples are prepared by varying the supplying time to vary the amount of aluminum adsorption. Then, the number of adsorbed aluminum atoms on each sample surface is determined, the proportion (%) of the adsorbed aluminum atom counts with respect to the aluminum saturation atom count being taken as the covering ratio.

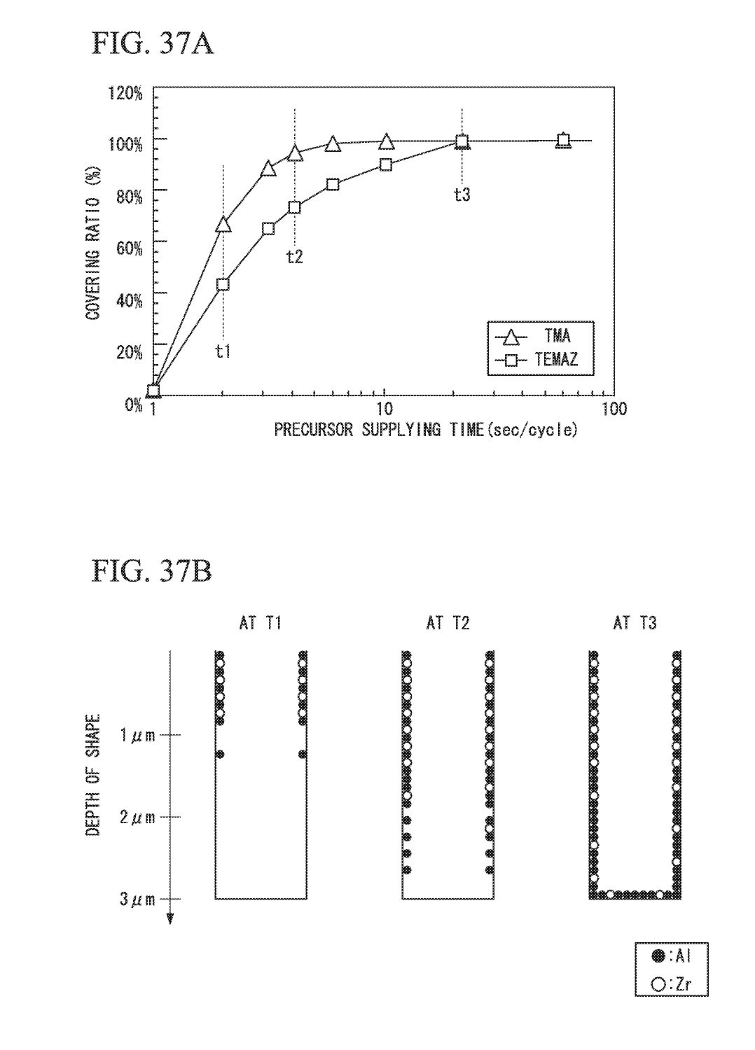

FIG. 37A shows the covering ratio for one cycle of each of the precursors, for the case in which TMA and TEMAZ at the same flow rates were supplied to the substrate for varying times, respectively. The horizontal axis represents the supplying time (second/cycle) of the precursors. The vertical axis represents the covering ratio of the precursors per one cycle. As is clear from FIG. 37A, for the case of TMA, the covering ratio is 100% when the supplying time is 10 seconds. In contrast, for the case of TEMAZ, it is seen that the covering ratio is 100% when the supplying time is 30 seconds. That is, between TMA and TEMAZ, there is a difference in the precursor covering characteristics with respect to the supplying time. It is hypothesized that a cause of such a difference in the precursor covering characteristics is that the difference is attributable to a difference in the rate of the gas-phase diffusion between the TMA that is the aluminum precursor and the TEMAZ that is the zirconium precursor. That is, the molecular weight of TMA is 72 and the molecular weight of TEMAZ is 323, which is approximately 4.5 times heavier than TMA, which may lead to the difference in diffusion rate. It is hypothesized that there is a difference in the time for the precursor molecules to cover the gas phase space over the substrate surface with a sufficient concentration.

FIG. 37B is a drawing, based on the above hypothesis, showing in schematic form, the condition of adsorption of the TMA and TEMAZ within a deep hole formed in a substrate surface. FIG. 37B shows the three cases at the times t1, t2, and t3 indicated in FIG. 37A. The time t1 is the amount of elapsed time at the start of supply, t2 is the amount of elapsed time when the only TMA coverage is nearly 100%, and t3 is the amount of elapsed time when the TMA coverage is 100% and when the TEMAZ coverage is nearly 100%.

The black circles symbolically indicate TMA, which is the aluminum precursor, and the white circles symbolically indicate TEMAZ, which is the zirconium precursor. After the elapsed time t1, although in the vicinity of the surface of the deep hole the adsorption rate of TMA and TEMAZ are substantially the same, in the center region of the deep hole, the adsorption of TMA, which has a high rate of diffusion progresses, and there is no adsorption of TEMAZ, which has a low rate of diffusion. After the elapsed time t2, although the TEMAZ begins to be adsorbed in the center region of the deep hole, because the majority of adsorption sites are already covered by TMA, the adsorption sites for TEMAZ are limited. Also, adsorption of TMA progresses to a further deeper part of the deep hole. At the elapsed time t3, almost all adsorption sites, including the bottom part of the deep hole are occupied by TMA, thereby further limiting the TEMAZ adsorption sites. Therefore, the delay in the reaching of TEMAZ is greater the greater is the depth position in the deep hole. Hence, the TMA adsorption progress faster than that of TEMAZ, and the TEMAZ adsorption is limited. As a result, as shown in the above-described FIG. 36, the value of the zirconium/aluminum ratio becomes smaller, the deeper is the position in the deep hold.

As noted above, in the deep hole in which TMA and TEMAZ, which have different covering characteristics with respect to the supplying time, are supplied in the same step, a difference in the zirconium/aluminum ratio depending upon the position in the depth direction occurs. As a result, a ZrAlO film having a zirconium/aluminum ratio that differs depending upon its position is formed, and it is difficult to control the leakage current and dielectric constant.

Given the above, the inventor performed an investigation regarding whether the above-noted covering characteristics could be made the same for TMA and TEMAZ. The diffusion rate is thought to be dependent upon the temperature of the gas phase space on the surface of the substrate and the concentration of the above-noted precursors. Given this, an attempt was made to investigate the covering characteristics of TMA and TEMAZ respectively for the case in which the temperature is varied. As a result, with regard to TMA, when the temperature was varied, the TMA supplying time for a 100% covering ratio varied, the supplying time shortening at the high-temperature end and lengthening at the low-temperature end. It was also discovered that ALD film formation is possible even if the temperature is varied over the range of 150 to 400° C. It was further discovered that, for TEMAZ, a gas phase reaction occurs at even higher temperature by 30° C. than 220° C., making ALD film formation itself difficult. Therefore, with ALD that supplies TMA and TEMAZ as precursors in the same step, it is difficult by optimizing the temperature to make the covering ratios the same, and ALD film formation with TEMAZ must be done in the optimum temperature range of 210 to 230° C.

Next, an investigation was done of the covering characteristics of TMA and TEMAZ for the case of varying the supplied amount. The supplied amount can be controlled by the amounts of TMA and TEMAZ liquid raw materials that are vaporized. As a result, it was learned that, for both TMA and TEMAZ, if the supplying time is held constant, the covering ratio is dependent on the supplied amount and becomes larger the greater is the supplied amount. From these experimental results, it was discovered that, in order to make the covering characteristics of TMA and TEMAZ substantially the same, it is effect to make the supplied amount of TEMAZ 2.5 to 3.5 times the supplied amount of TMA, and preferably set this at 3 times.

Also, although investigation was done regarding the flow amount of carrier gas for transporting the precursors into the reaction chamber and the dependency on the overall pressure within the reaction chamber, these conditions did not influence the covering characteristics.

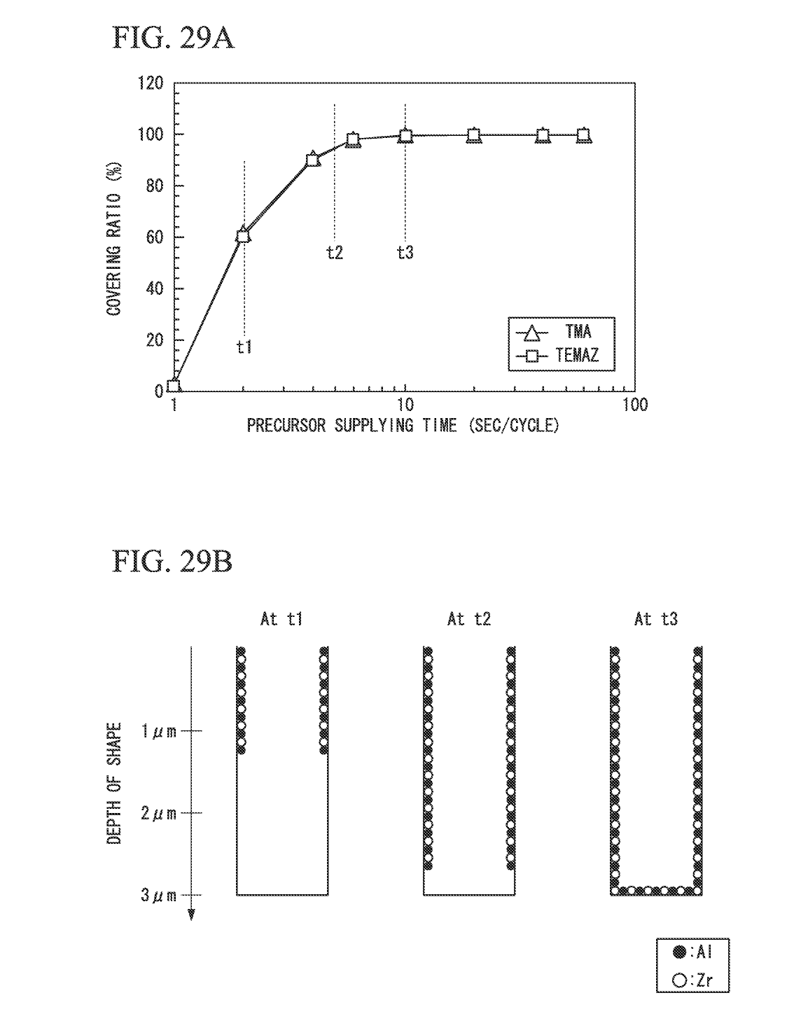

FIG. 29A shows an example of the supplying time dependency of the covering ratio with respect to a titanium nitride film in the case in which the TMA supplied amount is 0.2 slm and the TEMAZ supplied amount is 0.6 slm, with temperature of the reaction chamber, that is, the temperature of the semiconductor substrate at 220° C. The above-noted supplied amounts refer to the actually supplied amounts of TMA and TEMAZ themselves, and are not the amounts of carrier gas supplied. A titanium nitride film is a material of a lower electrode of a capacitor, and is formed on the semiconductor substrate using CVD. As is clear from FIG. 29A, the covering ratio is 100% at a supplying time of 10 seconds, and the covering characteristics are substantially the same for both TMA and TEMAZ.

FIG. 29B is a schematic representation showing the condition of TMA and TEMAZ adsorption within a deep hole formed in a semiconductor substrate surface, for the case in which the covering characteristics of TMA and TEMAZ are made the same.

The t1, t2, and t3 in FIG. 29B indicate the times t1, t2, and t3 that are shown in FIG. 29A. The time t1 is the amount of elapsed time at the start of supply, t2 is the amount of elapsed time when the TMA and TEMAZ coverage are nearly 100%, and t3 is the elapsed time when the TEMAX coverage is nearly 100%, with t3 being the elapsed time at which the coverage of both TMA and TEMAZ is 100%. The black circles symbolically indicate TMA, which is the AL precursor, and the white circles indicate TEMAZ, which is the zirconium precursor. Because the covering characteristics are substantially the same in this case, the adsorption rate is substantially the same for TMA and TEMAZ at any elapsed time.

Under conditions such as shown in FIG. 29A and FIG. 29B, it is possible to avoid the phenomenon shown in FIG. 37A and FIG. 37B of different adsorption ratios depending upon the position within the deep hole for gases having different covering characteristics. And also, it is possible to control the zirconium/aluminum ratio within a deep hold. For this reason, it is possible to make the zirconium/aluminum ratio substantially constant at any position within the deep hole.

Therefore, the present invention adopts the following constitution for the purpose of solving the above-described problems. The method for manufacturing a semiconductor memory device according to the present invention includes a step of forming a capacitor by a step of laminating a first electrode, a step of forming on the first electrode a capacitive insulating film containing at least two metal elements, and a step of laminating a second electrode on the capacitive insulating film, wherein the capacitive insulating film is formed by ALD wherein each of the precursors is simultaneously supplied to the semiconductor substrate surface using supplying conditions that are adjusted so that the precursor supplying time dependencies of the covering ratios of covering the first electrode surface for each of the precursors that contain the metal elements are the same.

According to one embodiment of the present invention, in the step of forming a capacitive insulating film containing at least two metal elements using ALD, at least two precursors containing different metal elements are supplied in the same step. The above-noted at least two precursors are supplied in the same step under a condition adjusted so that the supplying time dependencies of the covering of precursors on the lower electrode surface of the plurality are substantially the same.

By doing this, even in a three-dimensional structure in which a first electrode has a trench (deep hole), it is possible to form a capacitive insulating film made of an ALD film having a substantially uniform composition, over the bottom part and other overall regions of the deep hole of the first electrode. As a result, it is possible to control the occurrence of leakage current, and to form a semiconductor memory device having better refresh characteristics than in the case where the capacitive insulating film is formed as shown in FIGS. 37A and 37B.

Also, because the precursors are supplied in the same step and with flow amounts that make their covering characteristics substantially the same, it is not necessary to establish the overall source gas supplying time to adjust to the precursor having the longest film thickness saturation time.

For this reason, it is possible to shorten the precursor supplying time in forming an ALD film using at least two of precursors.

For this reason, it is possible to form an ALD film having a substantially uniform composition onto a member of a three-dimensional structure in a short time.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method for forming a semiconductor device may include, but is not limited to, the following processes. An insulating film is formed over a semiconductor substrate. A hole is formed in the insulating film. A film including ZrAlO is formed over the insulating film and in the hole. Forming the film including ZrAlO may include, but is not limited to, the following processes. A first precursor including zirconium and a second precursor including aluminum are supplied into a reaction chamber at a supply amount ratio of the first precursor to the second precursor in the range from 2.5 to 3.5. The first precursor and the second precursor are exhausted from the reaction chamber. An oxidant is supplied into the reaction chamber to oxidize zirconium and aluminum. The oxidant is exhausted from the reaction chamber.

In some cases, forming the film including ZrAlO may include, but is not limited to, the first period of time of supplying the first precursor at least partially overlapping a second period of time of supplying the second precursor.

In some cases, forming the film including ZrAlO may include, but is not limited to, the second period of time started during the first period of time.

In some cases, forming the film including ZrAlO may include, but is not limited to, supplying the first precursor and supplying the second precursor finished at substantially the same timing.

In some cases, forming the film including ZrAlO may further include, but is not limited to, repeating a first cycle. The first cycle may include, but is not limited to, supplying the first precursor and the second precursor, exhausting the first precursor and the second precursor, supplying the oxidant, and exhausting the oxidant.

In some cases, forming the film including ZrAlO may further include, but is not limited to, repeating a second cycle between the first cycles. The second cycle may include, but is not limited to, the following processes. The first precursor is supplied into the reaction chamber. The first precursor is exhausted from the reaction chamber. The oxidant is supplied into the reaction chamber to oxidize zirconium. The oxidant is exhausted from the reaction chamber.

In some cases, the forming the film including ZrAlO may include, but is not limited to, the number of performing the second cycle less than the number of performing the first cycle.

In some cases, the forming the film including ZrAlO may include, but is not limited to, the first precursor which is tetrakis(ethylmethylamino)zirconium and the second precursor which is trimethylaluminum.

In another embodiment, a method for forming a semiconductor device may include, but is not limited to, the following processes. An insulating film is formed over a semiconductor substrate. A hole is formed in the insulating film. A conductive film is formed over the insulating film and in the hole. A film including ZrAlO is formed over the conductive film by atomic layer deposition. Forming the film including ZrAlO may include, but is not limited to, the following processes. A first precursor including zirconium and a second precursor including aluminum are supplied into a reaction chamber to form a mono-molecular layer so that a first molecular ratio of the first precursor in the mono-molecular layer at a bottom of the hole is substantially the same as a second molecular ratio of the first precursor in the mono-molecular layer over a top surface of the insulating film. The first precursor and the second precursor are exhausted from the reaction chamber. An oxidant is supplied to the reaction chamber to oxidize zirconium and aluminum. The oxidant is exhausted from the reaction chamber.

In some cases, forming the film including ZrAlO may include, but is not limited to, the first period of time of supplying the first precursor at least partially overlapping a second period of time of supplying the second precursor.

In some cases, forming the film including ZrAlO may include, but is not limited to, the second period of time started during the first period of time.

In some cases, forming the film including ZrAlO may include, but is not limited to, supplying the first precursor and supplying the second precursor finished at substantially the same timing.

In some cases, forming the film including ZrAlO may further include, but is not limited to, repeating a first cycle. The first cycle may include, but is not limited to, supplying the first precursor and the second precursor, exhausting the first precursor and the second precursor, supplying the oxidant, and exhausting the oxidant.

In some cases, forming the film including ZrAlO may further include, but is not limited to, repeating a second cycle between the first cycles. The second cycle may include, but is not limited to, the following processes. The first precursor is supplied into the reaction chamber. The first precursor is exhausted from the reaction chamber. The oxidant is supplied into the reaction chamber to oxidize zirconium. The oxidant is exhausted from the reaction chamber.

In some cases, the forming the film including ZrAlO may include, but is not limited to, the number of performing the second cycle less than the number of performing the first cycle.

In some cases, the forming the film including ZrAlO may include, but is not limited to, the first precursor which is tetrakis(ethylmethylamino)zirconium and the second precursor which is trimethylaluminum.

In still another embodiment, a method for forming a semiconductor device may include, but is not limited to, the following processes. An insulating film is formed over a semiconductor substrate. A hole is formed in the insulating film. A first electrode is formed in the hole. A capacitive insulating film including ZrAlO is formed over the conductive film and the insulating film. A second electrode is formed over the capacitive insulating film. Forming the capacitive insulating film may include, but is not limited to, the following processes. A first precursor including zirconium and a second precursor including aluminum are supplied into a reaction chamber at a supply amount ratio of the first precursor to the second precursor in the range from 2.5 to 3.5. The first precursor and the second precursor are exhausted from the reaction chamber. An oxidant is supplied into the reaction chamber to oxidize zirconium and aluminum. The oxidant is exhausted from the reaction chamber.

In some cases, forming the hole may include, but is not limited to, forming the hole in the insulating film so that an aspect ratio of the hole is from 20 to 30.

Hereinafter, a semiconductor device according to an embodiment of the invention will be described in detail with reference to the drawings. As a convenience, in assisting understanding the features thereof, the drawings used in the following descriptions sometimes show such features enlarged, and the dimensional ratios and the like of constituent elements are not necessarily the same as a real semiconductor device. Also, the raw materials and dimensions and the like given as examples in the following descriptions are only examples, and the present invention is not restricted thereto, it being possible to embody arbitrarily variations within a scope that does not change the essence thereof.

### First Embodiment

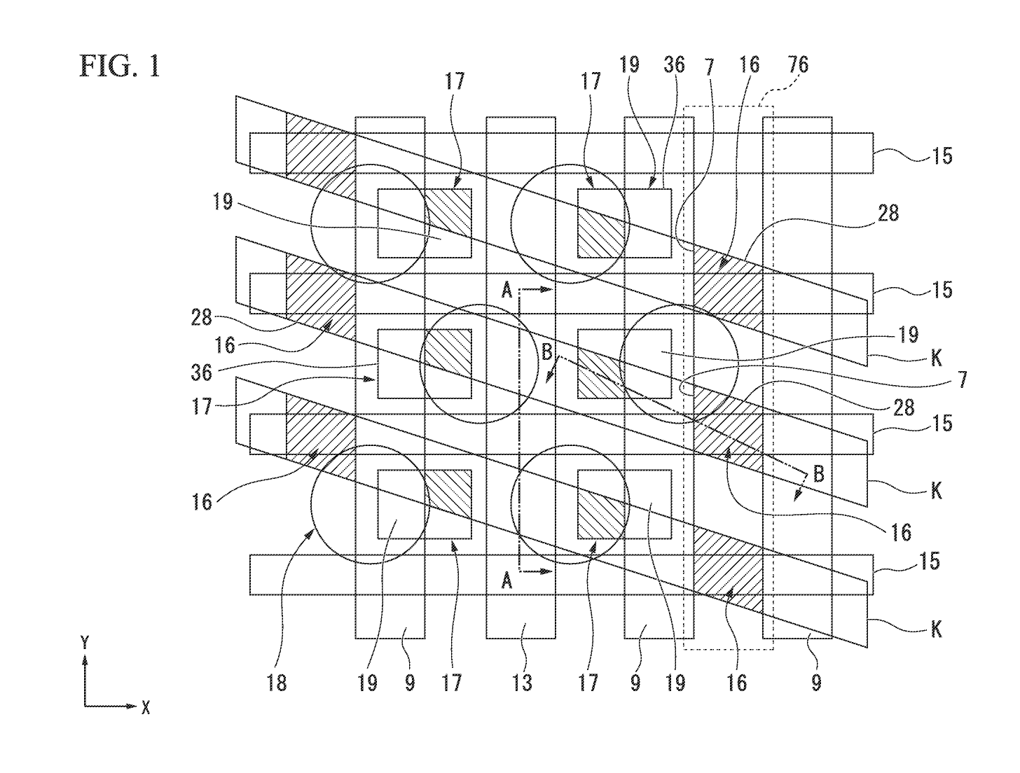

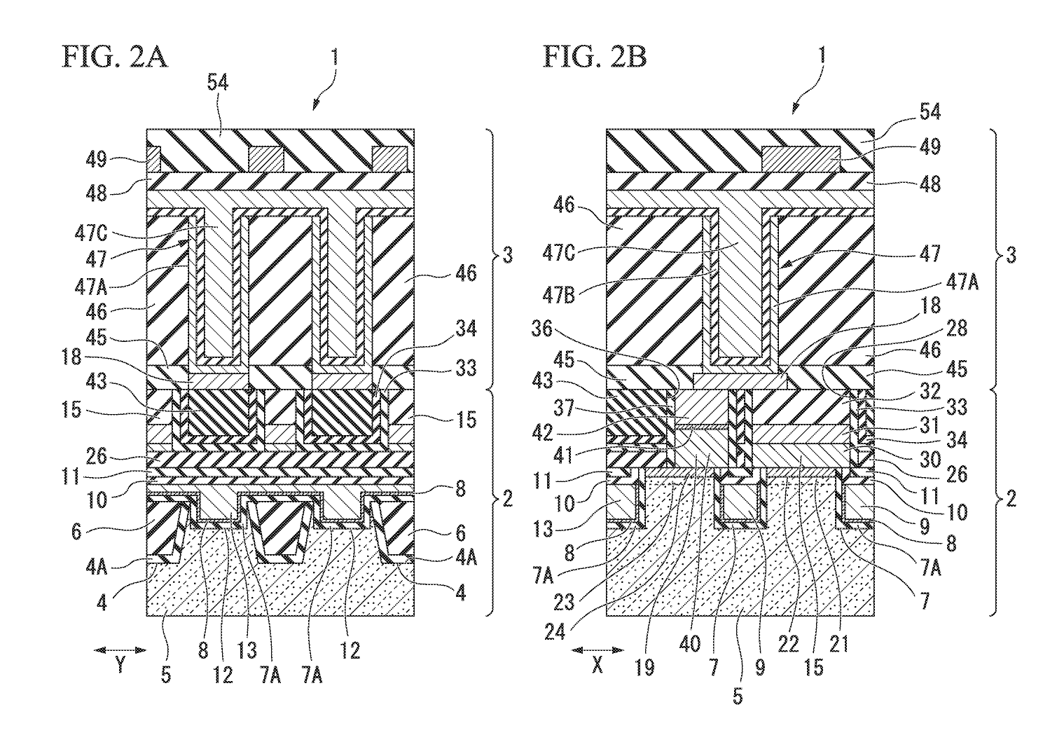

An example of a semiconductor memory device 1 formed by a method of forming the semiconductor memory device 1 of the present embodiment will be described. The method for forming the semiconductor memory device 1 of the present embodiment can be applied to the formation of various semiconductor memory devices including a capacitor, one example of which is shown in FIGS. 1, 2A, and 2B.

FIG. 1 is a fragmentary plan view illustrating a semiconductor device including a memory cell provided with a semiconductor memory device in accordance with a first preferred embodiment of the present invention. FIG. 2A is a fragmentary cross sectional elevation view, taken along with an A-A′ line of FIG. 1, illustrating the semiconductor device including the memory cell in accordance with the first preferred embodiment of the present invention. FIG. 2B is a fragmentary cross sectional elevation view, taken along with a B-B′ line of FIG. 1, illustrating the semiconductor device including the memory cell in accordance with the first preferred embodiment of the present invention.

The semiconductor memory device 1 may include, but is not limited to, a cell transistor formation region 2 and a cell capacitor formation region 3 as shown in cross-sectional view of FIG. 2A and FIG. 2B.

A semiconductor substrate 5 in which the cell transistor formation region 2 is formed may be a silicon substrate. The silicon substrate may be conductive. On the surface (one surface) of the semiconductor substrate 5, are formed a plurality of strip-shaped active regions K inclined at a prescribed angle with respect to the X direction as shown in FIG. 1 (a direction that is inclined toward the lower-right in FIG. 1) and separated by a prescribed spacing in the Y direction.

So as to partition the active regions K, a plurality of isolation trenches 4 having the cross-sectional shape shown in FIG. 2A are arranged so as to be inclined at a prescribed angle with respect the X direction in FIG. 1. The plurality of isolation trenches 4 are separated by a prescribed spacing in the Y direction in FIG. 1 and FIG. 2A.

As shown in FIG. 2A, an internal insulating film 4A which may include, but is not limited to, a silicon oxide film is formed on the inner surface of the isolation trench 4. An isolation insulating film 6 which may include, but is not limited to, a silicon nitride film is formed on the inner insulating film 4A so as to bury the isolation trench 4. By this constitution, an isolation region (STI region) made of the inner insulating film 4A and the isolation insulating film 6 are formed.

Although the plan view arrangement of the active regions K shown in FIG. 1 is one feature of the present embodiment, the shape or arrangement direction of the active regions K is not limited thereto. It is obviously understood that the shape of the active regions shown in FIG. 1 can be a shape of active regions applied to other general transistors, and is not restricted to the shape in the present embodiment.

As shown in FIG. 2B, a plurality of gate electrode trenches 7 extend in the Y direction of FIG. 1. The plurality of gate electrode trenches 7 are separated by a prescribed spacing in the X direction of FIG. 1 and FIG. 2B. A gate insulating film 7A which may include, but is not limited to, a silicon oxide film is formed on the inner surface of the gate electrode trench 7. An inner surface layer 8 which may include, but is not limited to, titanium nitride or the like is formed on the gate insulating film 7A. A buried word line 9 which may include, but is not limited to, a high melting point metal such as tungsten, is formed so as to bury the gate electrode trench 7. The inner surface layer 8 and gate insulating film 7A are interposed between the inner surface of the gate electrode trench 7 and the buried word line 9. A buried insulating film 11 is formed over the buried word line 9 so as to bury the gate electrode trench 7. A liner film 10 is interposed between the buried word line 9 and the buried insulating film 11.

In FIG. 1, the gate electrode trench 7, in which the buried word line 9 is formed, has a first portion and a second portion. The first portion is formed at the part overlaps with the active region K. The semiconductor substrate in the vicinity of the first portion serves as a channel of a trench gate transistor. The second portion is shallower than the first portion and is formed in the STI region adjacent to the active region K. These two types of trenches with different depths are buried, thereby forming the buried word line 9 as one continuously wiring having a planar upper surface.

According to the semiconductor memory device 1 formed by the present embodiment, the gate electrode insulating film 7A and the liner film 10 are formed so that the top surface thereof reach the aperture part of the gate electrode trench 7. In other words, the gate electrode insulating film 7A and the liner film 10 are formed so that the top surface thereof are leveled with the surface of the semiconductor substrate 5. The buried insulating film 11 is formed so as to bury the recessed part over the liner film 10. The buried insulating film 11, the gate electrode insulating film 7A, and the liner film 10 are laminated so that the upper surface of the buried insulating film 11, the upper end of the gate electrode insulating film 7A, and the upper end of the liner film 10 are substantially flush with one another.

The buried insulating film 11 may include, but is not limited to, a silicon oxide film formed by CVD, an application film such as an SOD film (spin-on-dielectric: polysilazane or the like coated insulating film) formed by annealing in a high-temperature, water-containing atmosphere to obtain a solid film, or the like.

As shown in FIG. 2A, a channel trench 12 that is shallower than the isolation trench 4 is formed in a region between the isolation trenches 4 that are adjacent in the Y direction. The gate insulating film 7A that may include, but is not limited to, a silicon oxide film is formed on the inner surface of the channel trench 12 and the upper surface of the element separation trenches 4, which are adjacent to the channel trench 12. The gate insulating film 7A passes across the channel trench 12. A buried wiring 13 for element isolation is formed on the gate insulating film 7A. An inner surface layer 8 that may include, but is not limited to, titanium nitride or the like is interposed between buried wiring 13 and the inner surface layer 8. The liner film 10 and the buried insulating film 11 are laminated over the buried wiring 13. The liner film 10 and the buried insulating film 11 shown in FIG. 2A are formed in the same step with the liner film 10 and the buried insulating film 11 formed over the buried word line 9 shown in FIG. 2B, using the same film in the method for forming the semiconductor device to be described later.

The buried wiring 13 for element isolation is formed in the same step with the buried word line 9. The buried wiring 13 for element isolation, in the active region that is formed to have a linear shape, electrically isolates the adjacent source region and drain region that constitute each of the transistors (the impurity diffusion regions formed on both side of the buried wiring 13 for element isolation shown in FIG. 1). Although in the related art, an active region is formed as an isolated pattern surrounded by an isolation region that is formed by burying with an insulating film. Because of insufficient lithography resolution, it is difficult to form the desired shape in the source and drain regions formed at the edge parts of an active region. According to the present embodiment, however, because active region pattern is formed to have a linear shape, the above-noted phenomenon can be avoided.

Although as shown in FIG. 1, and FIG. 2B, the plurality of buried word lines 9 are formed so as to extend in the Y direction and be separated from one another in the X direction. As shown in FIG. 2B, according to the semiconductor memory device 1 of the present embodiment, two buried word lines 9 and one buried interconnect 13 for element isolation are arranged in this sequence alternately in the X direction.

As shown in FIG. 1, the bit wiring 15 is formed to be arranged in a direction that is perpendicular with respect to the buried word lines 9 and the buried wiring 13. A bit wiring connection region 16 is defined at a part of the active region K positioned below each of the bit wirings 15. As shown in FIG. 1, with the wiring structure seen in plan view, a capacitor contact plug formation region 17 is defined in a region between the buried word line 9 and the buried wiring 13 for element isolation that are adjacent in the X direction, and the region between bit wirings 15, 15 that are adjacent in the Y direction. Capacitor contact pads 18 are formed with respect to the capacitor contact plug formation regions 17 in alternately offset positions in the Y direction shown in FIG. 1. These capacitor contact pads 18 are disposed between the bit wirings 15, 15 in the X direction that are adjacent in the Y direction in FIG. 1. The capacitor contact pads 18 are disposed respectively in alternating offset manner, with the center of each disposed over every other buried word line 9 in the Y direction, or the center of each disposed above the side of every other buried word line 9 in the Y direction. In other words, the capacitor contact pads 18 are arranged in a staggered arrangement in the Y direction.

The capacitor contact plugs 19 formed in the capacitor contact plug formation regions 17 are formed to be rectangularly shaped as shown in FIG. 1 in the present embodiment. One part of the capacitor contact plug 19 is positioned over the buried word line 9, and the other part of the capacitor contact plug 19 is positioned in a region between the bit wirings 15, 15, which are adjacent and above the region between the buried word line 9 and the buried interconnect 13 for element isolation. The capacitor contact plugs 19 are respectively connected to capacitors 47, to be described later.

In FIG. 1, the capacitor contact plug formation region 17, when seen in plan view, straddles across part of a buried word line 9, part of an STI region, and part of an active region K. When seen in plan view, therefore, the capacitor contact plug 19 is formed to straddle across part of a buried word line 9, part of an STI region, and part of an active region K.

The cell transistor formation region 2 will be further described based on FIG. 2A and FIG. 2B. In a region between the buried word lines 9, 9 adjacent in the X direction as shown in FIG. 2B and corresponding to the above-noted active region K, a low-concentration impurity diffusion layer 21 and a high-concentration impurity diffusion layer 22 are formed. The high-concentration impurity diffusion layer 22 is positioned over the low-concentration impurity diffusion layer 21. On the surface side of the semiconductor substrate 5 positioned between the buried word line 9 and the buried wiring 13 for element isolation adjacent in the X direction and a region corresponding to the active region K, a low-concentration impurity diffusion layer 23 and a high-concentration impurity diffusion layer 24 are formed. The high-concentration impurity diffusion layer 24 is positioned over the low-concentration impurity diffusion layer 23.

A first interlayer insulating film 26 covers the buried insulating film 11 as shown in FIG. 2A. As shown in FIG. 2B, the first interlayer insulating film 26 covers the surface of the semiconductor substrate 5. The first interlayer insulating film 26 covers the high-concentration impurity diffusion layers 22 and 24 and the gate electrode trench 7 in which the buried word line 9, the liner layer 10, and the buried insulating film 11 are formed.

A contact hole 28 is formed in the first interlayer insulating film 26. The contact hole 28 is positioned in a region between gate electrode trenches 7 that are adjacent in the X direction of FIG. 2B. As shown in FIG. 1, the bit wirings 15 extend in a direction that is perpendicular with respect to the buried word lines 9 on the first interlayer insulating film 26. The bit wirings 15 are positioned on the bottom part of the contact holes 28, and are connected to the high-concentration impurity diffusion layers 22. Therefore, the bit wiring connection region 16 is defined as a region in which the bit wiring 15 exists in the contact hole 28 and the region therebelow in which the high-concentration impurity diffusion layer 22 exists.

The bit wiring 15 has a three-layer structure made of a bottom part conductive film 30, a metal film 31, and an upper insulating film 32. The bottom part conductive film 30 may include, but is not limited to, impurity-doped polysilicon. The metal film 31 may include, but is not limited to, a high melting point metal such as tungsten. The upper insulating film 32 may include, but is not limited to, a silicon nitride film or the like. As shown in FIG. 2B, an insulating film 33 and a liner film 34 are positioned on both sides of the bit wiring 15 in the width direction. The insulating film 33 and the liner film 34 are positioned on both sides of the bit wiring 15 above the first interlayer insulating film 26 shown in FIG. 2A. The insulating film 33 may include, but is not limited to, a silicon nitride film or the like.

In a region that is between bit wirings 15 that are adjacent in the Y direction shown in FIG. 1 and also that is between the region above the buried word line 9 and the buried wiring 13 for element isolation adjacent to the buried word line 9, a capacitor contact aperture 36 is positioned. The capacitor contact aperture 36 has a rectangular shape when seen in plan view. A capacitor contact plug 19 is disposed in the capacitor contact aperture 36 so as to be surrounded by the side wall 37. The side wall 37 may include, but is not limited to, a silicon nitride film or the like. The part at which the capacitor contact aperture 36 is formed corresponds to the capacitor contact plug formation region 17. The capacitor contact plug 19, as shown in FIG. 2B, has a three-layer structure made of a bottom part conductive film 40, a silicide layer 41, and a metal film 42. The bottom part conductive film 40 may include, but is not limited to, polysilicon or the like. The silicide layer 41 may include, but is not limited to, CoSi or the like. The metal film 42 may include, but is not limited to, tungsten or the like. The bit wiring 15 and the capacitor contact plug 19 are formed with the same height over the semiconductor substrate 5. A buried insulating film 43 is formed so as to have a height that is the same as the bit wiring 15 and the capacitor contact plug 19 over the semiconductor substrate 5.

As shown in FIG. 2A and FIG. 2B, in the capacitor formation regions 3 the capacitor contact pads 18 are formed above the capacitor contact plugs 19. The capacitor contact pads 18 alternately offset so as to partially overlap with the capacitor contact plugs 19 when seen in plan view in FIG. 1. Each capacitor contact pad 18 is covered by a stopper film 45. A third interlayer insulating film 46 is formed over the stopper film 45. In the third interlayer insulating film 46, the capacitor 47 is positioned over the capacitor contact pad 18.

The capacitor 47 is constituted by a cylindrically shaped lower electrode 47A, a capacitive insulating film 47B, and an upper electrode 47C. The cylindrically shaped lower electrode 47A is positioned above the capacitor contact pad 18. The capacitive insulating film 47B is positioned on the lower electrode 47A and extends above the third interlayer insulating film 46. The upper electrode 47C buries a space surrounded by the capacitive insulating film 47B. The capacitive insulating film 47B is interposed between the lower electrode 47A and the upper electrode 47C. Also, the upper electrode 47C extends above the capacitive insulating film 47B which is positioned above the third interlayer insulating film 36.

A fourth interlayer insulating film 48 covers the upper electrode 47C. An upper metal wiring 49 is positioned above the fourth interlayer insulating film 48. A protective film 54 covers the upper metal wiring 49 and the fourth interlayer insulating film 48. The structure of the capacitor 47 is one example and, another capacitor structure generally applied to semiconductor memory devices, such as a crown type structure, may be applied as a structure other than that of the present embodiment.

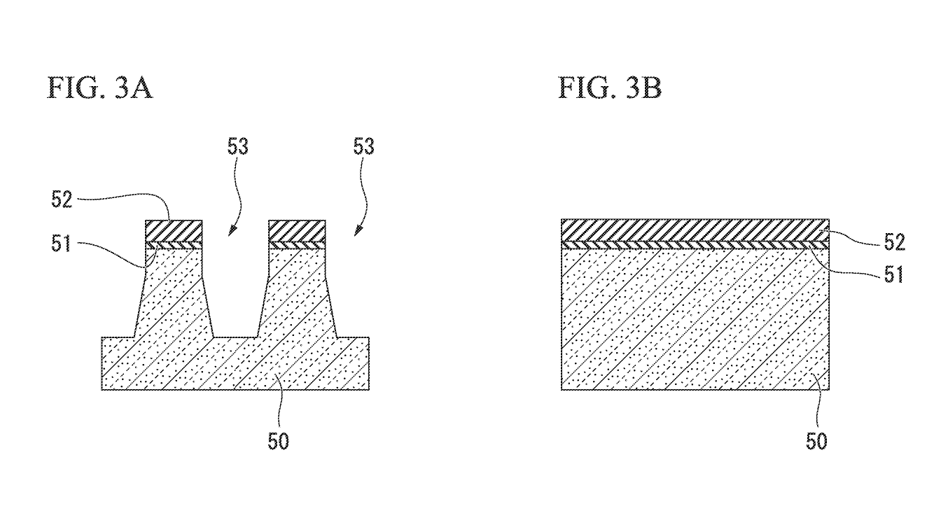

A method for forming the semiconductor memory device 1 shown in FIGS. 1, 2A and 2B will be described with reference to FIGS. 3A to 23B. FIGS. 3A, 4A, 5A, 6A, 7A, 8A, 9A, 10A, 11A, 12A, 13A, 14A, 15A, 16A, 17A, 18A, 19A, 20A, 21A, 22A, and 23A are fragmentary cross sectional elevation views, taken along with the A-A′ line of FIG. 1, illustrating the semiconductor device in a step involved in the method of forming the semiconductor device of FIG. 1 in accordance with a first preferred embodiment of the present invention. FIGS. 3B, 4B, 5B, 6B, 7B, 8B, 9B, 10B, 11B, 12B, 13B, 14B, 15B, 16B, 17B, 18B, 19B, 20B, 21B, 22B, and 23B are fragmentary cross sectional elevation views, taken along with the B-B′ line of FIG. 1, illustrating the semiconductor device in a step involved in the method of forming the semiconductor device of FIG. 1 in accordance with a first preferred embodiment of the present invention.

First, as shown in FIG. 3A and FIG. 3B, a silicon oxide film 51 and a silicon nitride film (Si₃N₄ film) 52 which will be used as a mask, are sequentially laminated onto a semiconductor substrate 50. The semiconductor substrate may be, but is not limited to, a p-type Si substrate or the like.

Using a photolithography process and a dry etching process, the silicon oxide film 51, the silicon nitride film 52, and the semiconductor substrate 50 are patterned. An isolation trench 53 is formed to define the active region K. For example, the isolation region 53 is formed as a linear pattern trench extending in a first direction so as to sandwich both sides of the strip-shaped active regions K in FIG. 1 when the semiconductor substrate 50 is seen in plan view, the. The regions to be the active regions K are covered by the silicon nitride film 52.

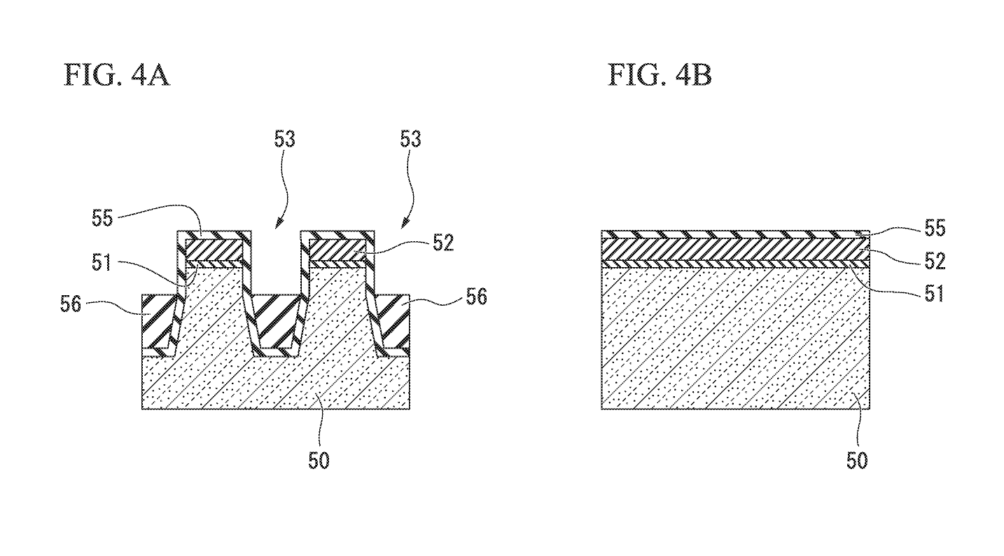

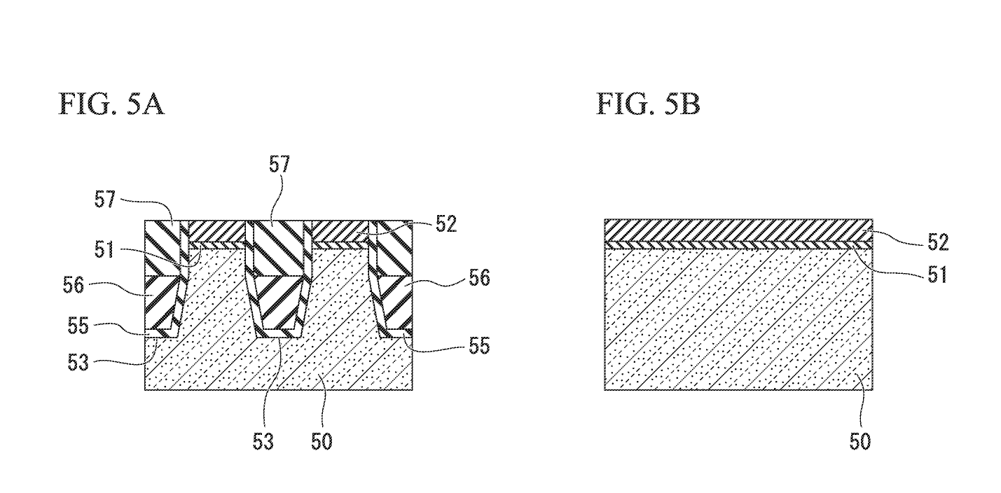

As shown in FIG. 4A and FIG. 4B, a silicon oxide film 55 is formed on the surface of the semiconductor substrate 50. After that, a silicon nitride film is deposited so as to fill the inside of the isolation region 53. Then, an etching back process is performed to form an isolation insulating film 56 whose top surface is a little bit lower than a top surface of the semiconductor substrate 50. A silicon oxide film 57 is deposited by CVD so as to fill the inside of the isolation trench 53. CMP (chemical mechanical polishing) is performed until the silicon nitride film 52 is exposed, so as to planarize the surface of the silicon oxide film 57 and the silicon nitride film 52 as shown in FIG. 5A and FIG. 5B.

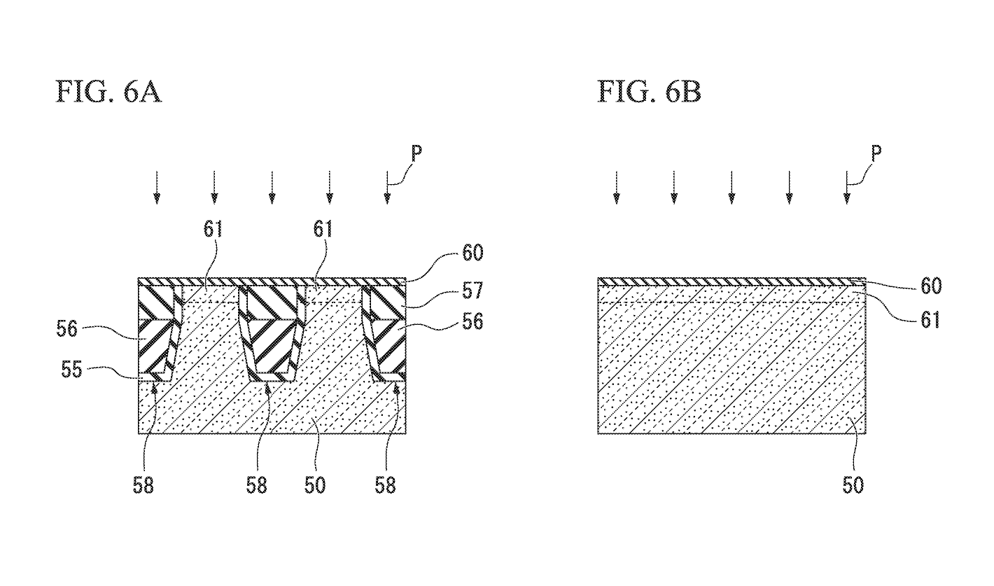

An isolation region 58 is formed as shown in FIG. 6A and FIG. 6B. The silicon nitride film 52 and the silicon oxide film 51 are removed by a wet etching process, so that a top surface of the silicon oxide film 57 which is positioned in the isolation trench 53 is at substantially the same position as the top surface of the semiconductor substrate 50. By doing this, the linear isolation region 58 using STI (shallow trench isolation) is formed. By forming the isolation region 58, the plurality of active regions K are insulated and isolated. A silicon oxide film 60 is formed on the surface of the semiconductor substrate 50 by thermal oxidation. After that, an n-type low-concentration impurity element (phosphorus or the like) is ion implanted, thereby forming an n-type low-concentration impurity diffusion layer 61. The n-type low-concentration impurity diffusion layer 61 functions as part of the source or drain region of the recessed transistor of the present embodiment.

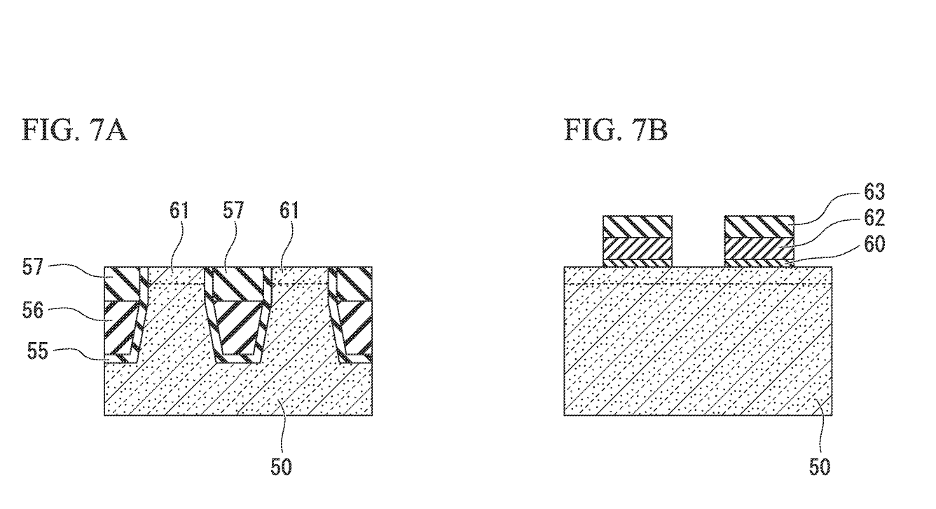

As shown in FIG. 7A and FIG. 7B, a silicon nitride film 62 which will be used as a mask, and a carbon film (amorphous carbon film) 63 are sequentially deposited and patterned for the formation of a gate electrode trench.

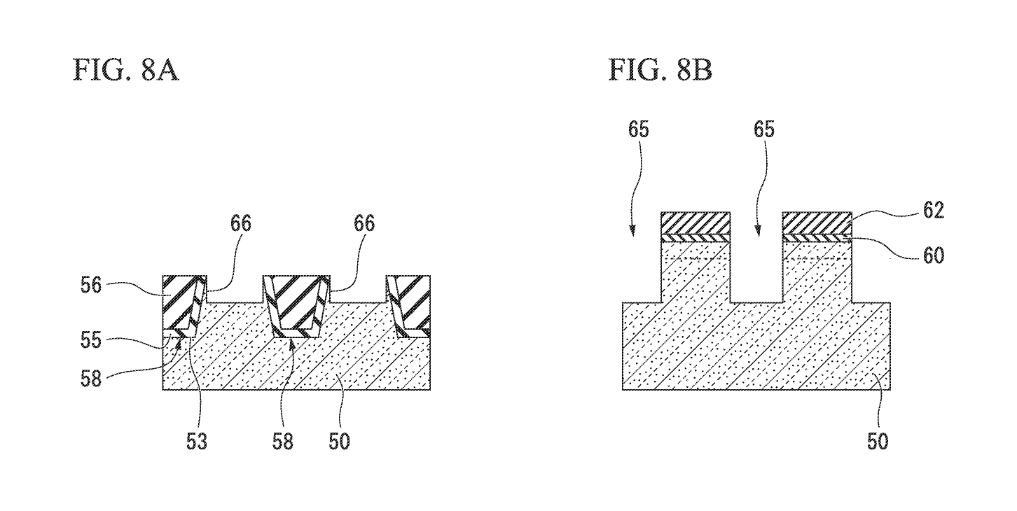

As shown in FIG. 8A and FIG. 8A, the semiconductor substrate 50 is etched so as to form trenches (gate electrode trenches) 65. These trenches 65 are formed as a linear pattern that extends in a second direction (Y direction in FIG. 1) that is perpendicular with respect to the active regions K. A thin-film of silicon remains as a side wall 66, which is a side wall of the trenches 65, on the side surface of the isolation region 58, this functioning as the channel region of a recess-type cell transistor.

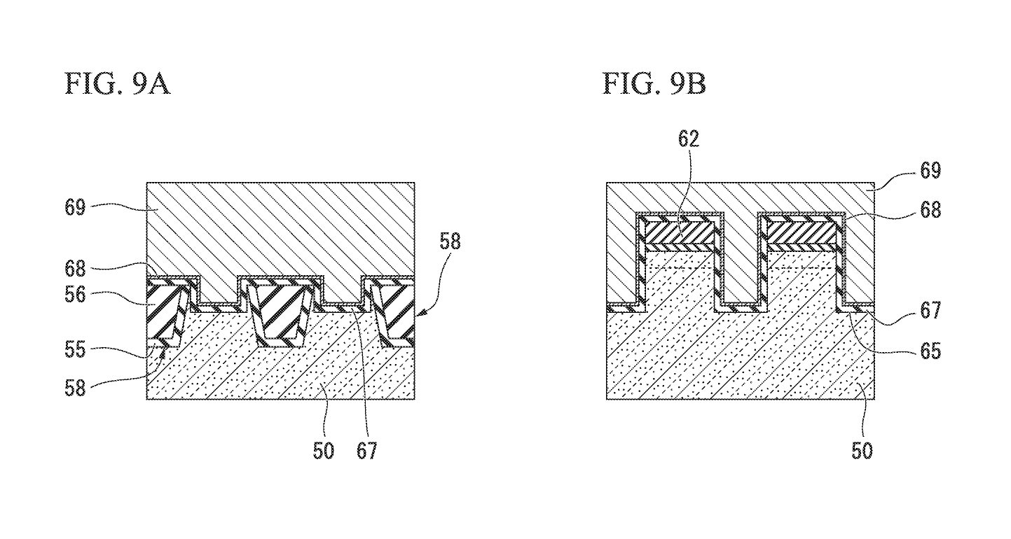

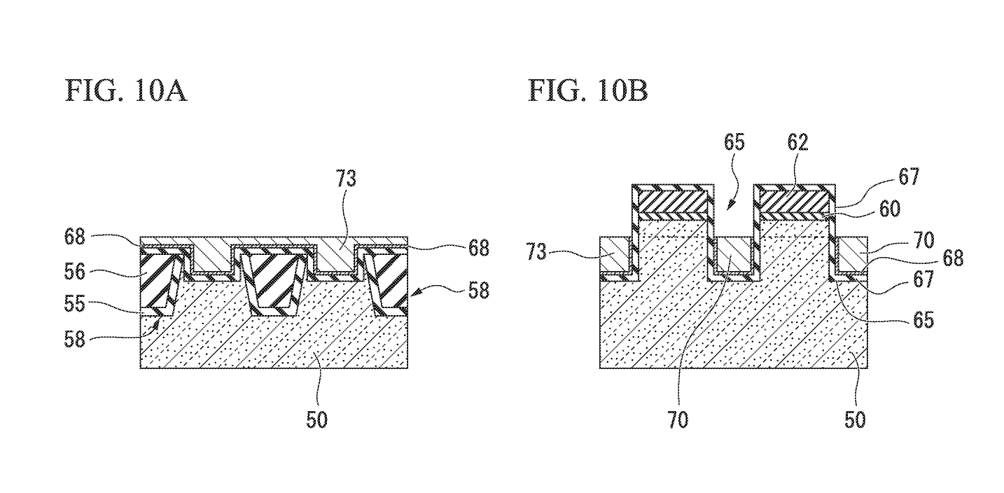

As shown in FIG. 9A and FIG. 9B, a gate insulating film 67 which may include, but is not limited to, a silicon oxide film or the like is formed. After that, an inner surface layer 68 which may include, but is not limited to, titanium nitride (TiN) and a tungsten (W) layer 69 are sequentially deposited. An etching back process is performed so as to leave the inner surface layer 68 and the tungsten layer 69 on the lower inside of the trench 65. By doing this, a buried word line 70 a part of which serves as the gate electrode, and a buried wiring 73 for element isolation are formed, as shown in FIG. 10A and FIG. 10B.

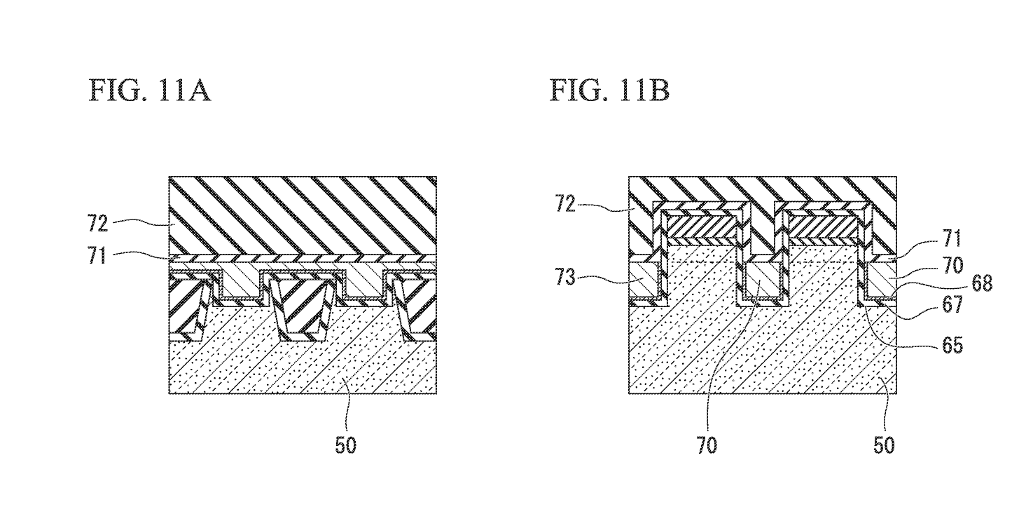

As shown in FIG. 11A and FIG. 11B, a liner film 71 with a thickness of approximately 10 nm is formed so as to cover the remaining tungsten layer 69 and the inner wall of the trench 65. The liner film 71 may include, but is not limited to, a silicon nitride film (Si₃Ni₄) or the like. A buried insulating film 72 is deposited over the liner film 71 by CVD.

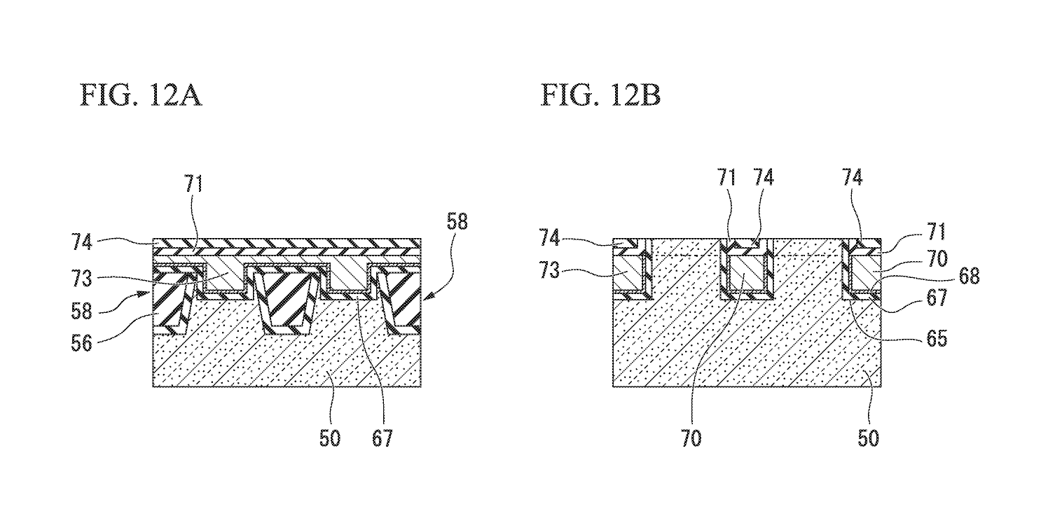

A surface of the buried insulating film 72 is planarized by CMP until the liner film 71 is exposed, as shown in FIG. 12A and FIG. 12B. The silicon nitride film used as a mask, part of the buried insulating film 72, and part of the liner film 71 are removed by an etching process. The surface of the buried insulating film 72 is made substantially the same height as the top surface of the semiconductor substrate 50. By doing this, one surface of the semiconductor substrate 50 other than the gate electrode trench 65 and the liner film 71 in the gate electrode trench 65 are exposed. By the above, the buried word line 70 and the buried wiring 73 for element isolation are formed. A buried insulating film 74 is formed over the liner film 71 which is positioned at the upper part of the gate electrode trench 65.

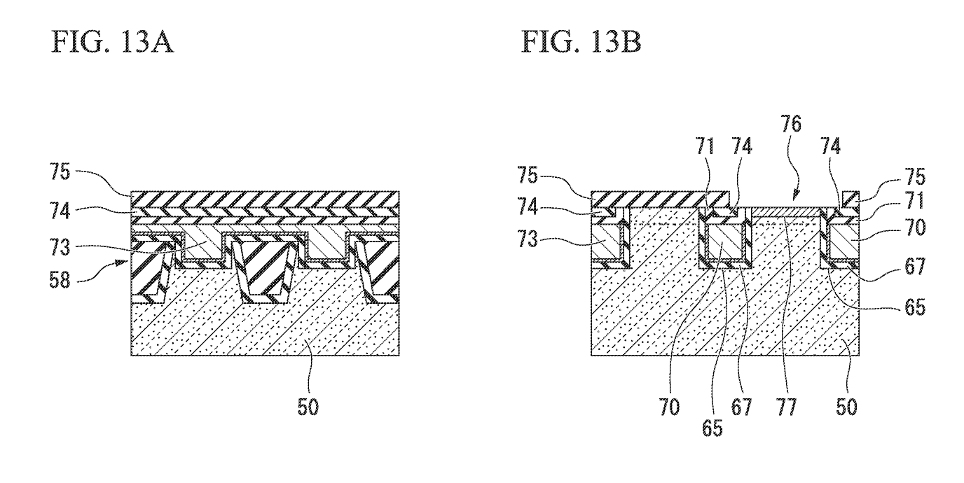

As shown in FIG. 13A and FIG. 13B, a first interlayer insulating film 75 made of a silicon oxide film or the like is formed so as to cover the semiconductor substrate 50. After that, part of the first interlayer insulating film 75 is removed to form a bit contact aperture 76. The bit contact aperture 76 is formed as a linear pattern that extends in the same direction as the buried word line 70 (the Y direction in FIG. 1 and the direction of extension of the buried word line 70 and buried wiring 73 in FIG. 13). By doing this, the silicon surface of the semiconductor substrate 50 is exposed in part at which the bit contact aperture 76 intersects with the active region K. An n-type impurity element (arsenic or the like) is ion implanted, thereby forming an n-type high-concentration impurity diffusion layer 77 in the vicinity of the silicon surface of the semiconductor substrate 50. The n-type high-concentration impurity diffusion layer 77 functions as the source or drain region of the recessed cell transistor.

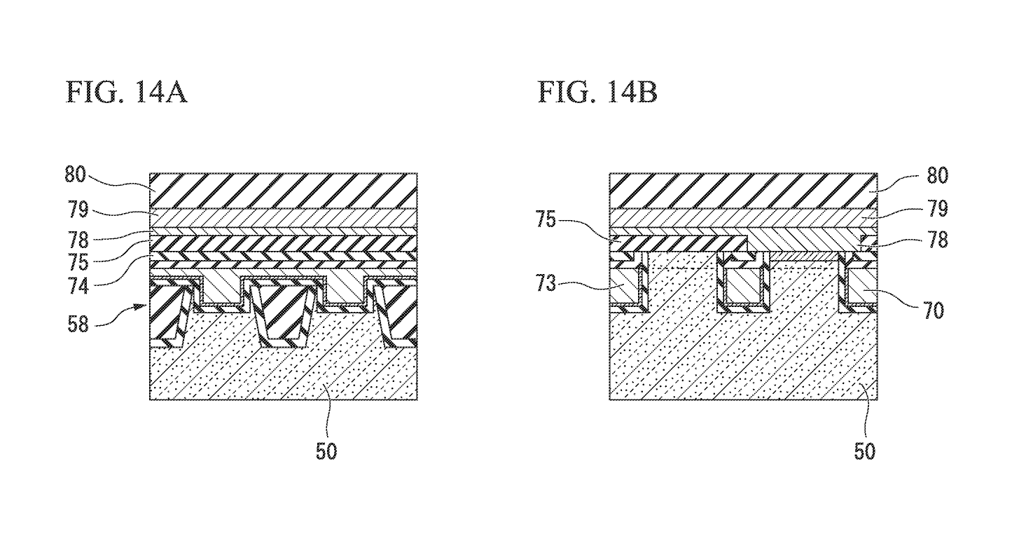

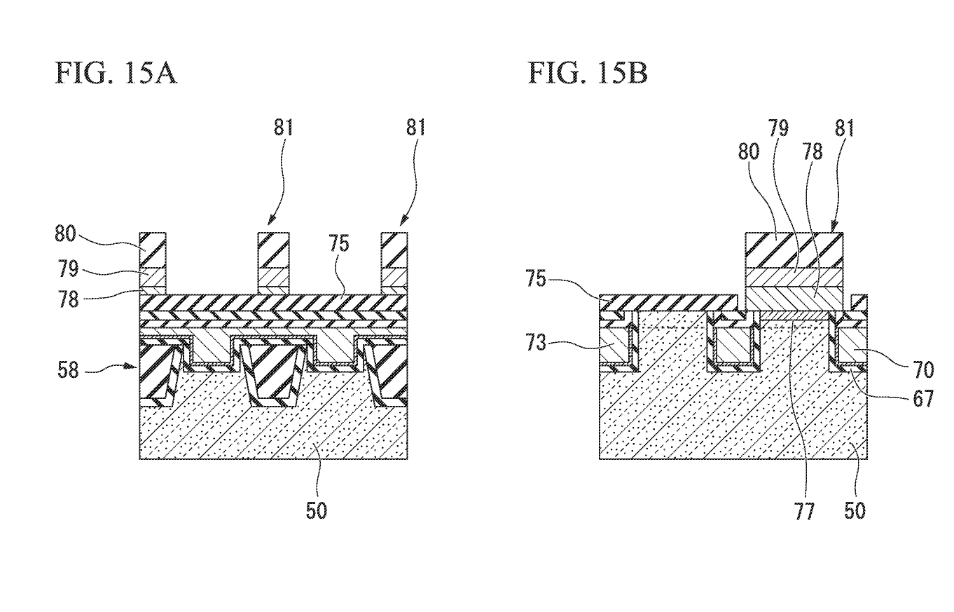

As shown in FIG. 14A and FIG. 14B, a bottom conductive film 78, a metal film 79 such as a tungsten film, and a silicon nitride film (insulating film) 80 are sequentially deposited over the semiconductor substrate 50. The bottom conductive film 78 may be, but is not limited to, a polysilicon film that contains an n-type impurity (phosphorus or the like). The metal film 79 may be, but is not limited to, a tungsten film. As shown in FIG. 15A and FIG. 15B, by patterning the film laminate made of the bottom conductive film 78, the metal film 79, and the silicon nitride film 80 in a linear pattern, a bit wiring 81 is formed. The bit wiring 81 is formed as a pattern that extends in a direction that intersects with the buried word line 70 (the X direction shown in FIG. 1). The bottom part conductive film 78 which is the lower layer of the bit interconnect 81 is connected to the n-type high-concentration impurity diffusion layer 77 (one of the source and drain region) which is the surface part of the semiconductor substrate 50. The surface part of the semiconductor substrate 50 shown through the bit contact aperture 76 corresponds to the n-type high-concentration impurity diffusion layer 77.

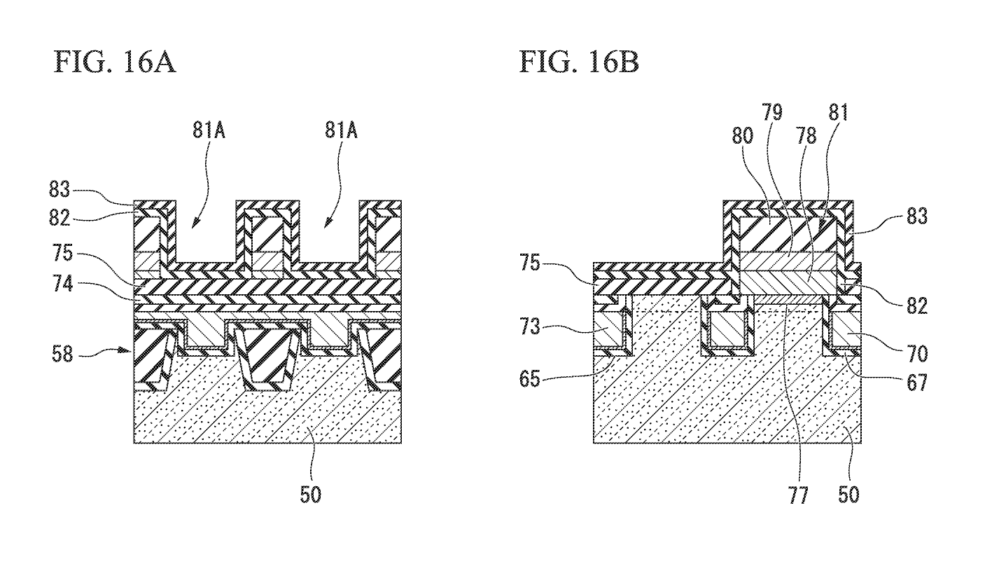

As shown in FIG. 16A and FIG. 16B, after forming a silicon nitride film 82 that covers the side surface of the bit wiring 81, a liner film 83 is formed so as to cover the silicon nitride film 82. The liner film 83 may include, but is not limited to, a silicon nitride film or the like.

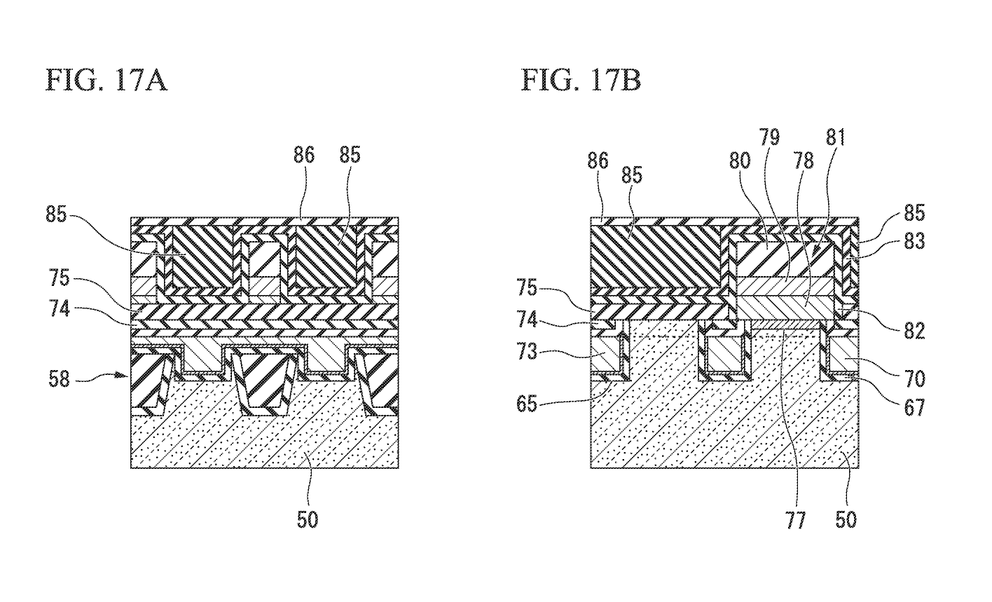

As shown in FIG. 17A and FIG. 17B, a deposited film 85 is formed so as to fill the space 81A between the bit wirings 81, 81. After performing planarization by CMP until the upper surface of the liner film 83 is exposed, a second interlayer insulating film 86 is formed so as to cover the deposited film 85.

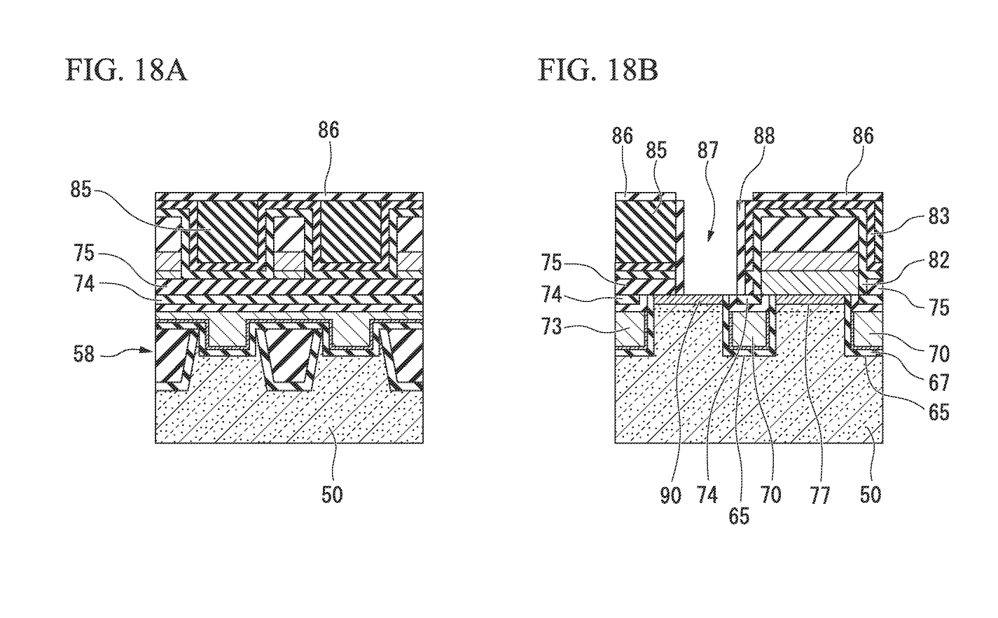

As shown in FIG. 18A and FIG. 18B, a capacitor contact aperture 87 is formed at a position corresponding to the capacitor contact plug formation region 17. By doing this, the surface of the semiconductor substrate 50 is exposed in the part at which the capacitor contact aperture 87 intersects with the active region K. A side wall (SW) 88 which may be, but is not limited to, a silicon nitride film is formed so as to cover a side wall of the capacitor contact aperture 87. An n-type impurity (phosphorus or the like) is ion implanted into the surface of the semiconductor substrate 50, so as to form an n-type high-concentration impurity diffusion layer 90 in the vicinity of the surface of the semiconductor substrate 50. The n-type high-concentration impurity diffusion layer 90 functions as the source or drain region of a recess-type transistor of the present embodiment.

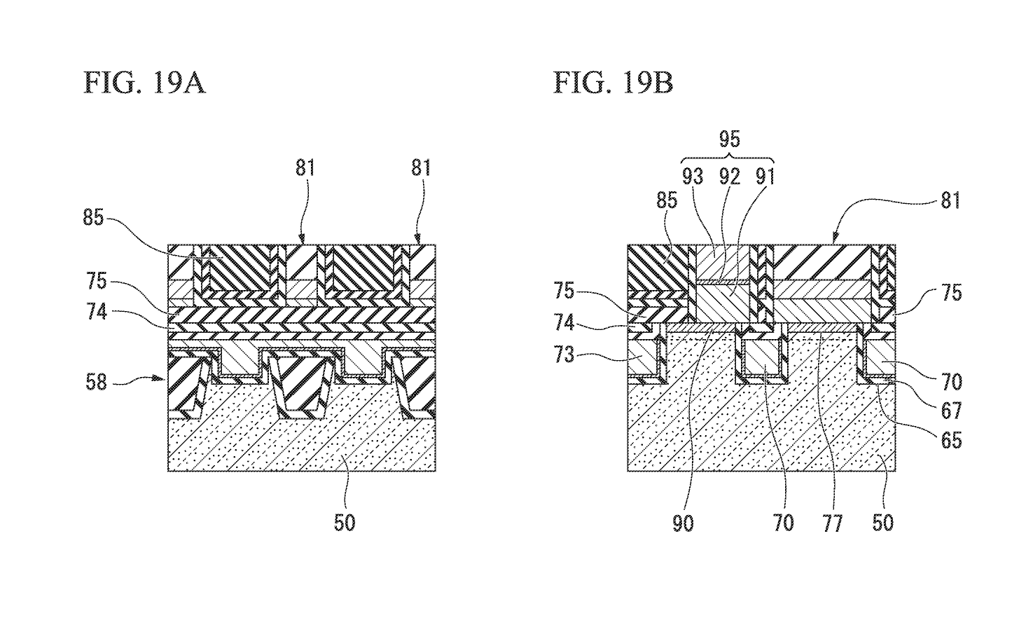

As shown in FIG. 19A and FIG. 19B, a bottom conductive film 91 is formed. A silicide layer 92 which may include, but is not limited to, cobalt silicide (CoSi) or the like is formed on the bottom part conductive film 91. A metal film 93 which may include, but is not limited to, tungsten or the like is deposited on the silicide layer so as to fill the capacitor contact aperture 87. By doing this, a capacitor contact plug 95 having a three-layer structure is formed.

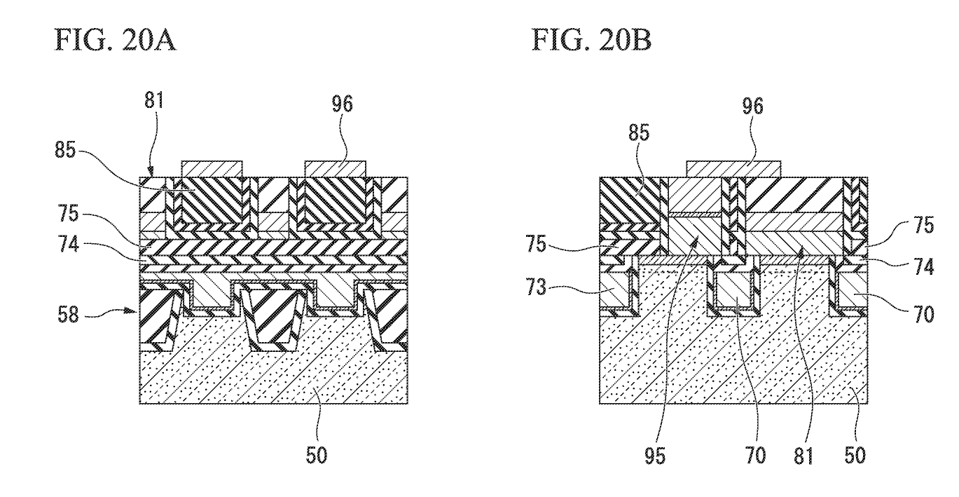

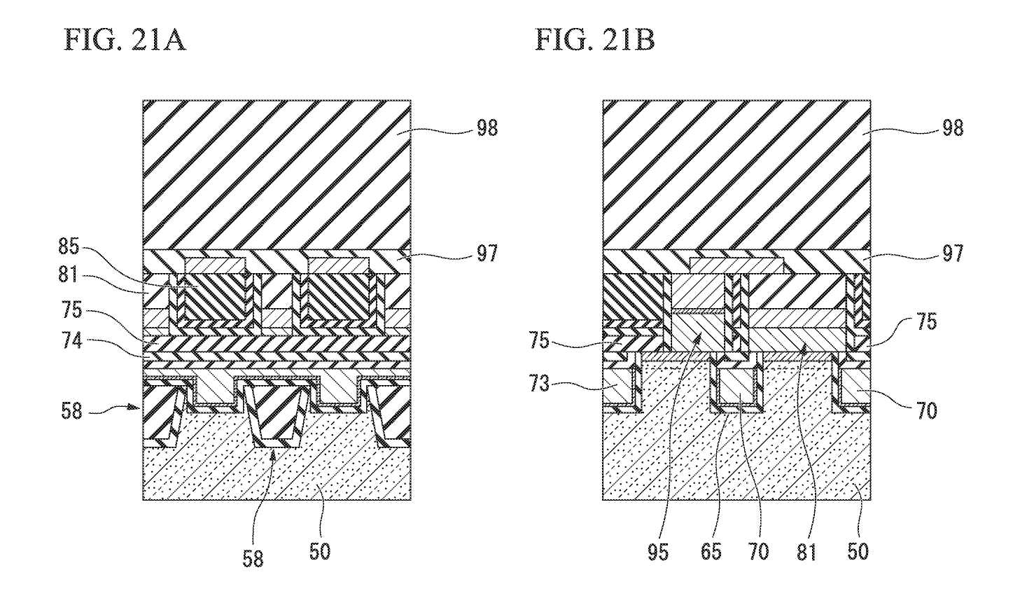

By sequential depositing a tungsten nitride (WN) film and a tungsten (W) film and patterning the tungsten nitride film and the tungsten film, the capacitor contact pad 96 is formed. The capacitor contact pad 96 is connected to the capacitor contact plug 95 as shown in FIG. 20A and FIG. 20B. As shown in FIG. 21A and FIG. 21B, a stopper film 97 which may be, but is not limited to, a silicon nitride film and a third interlayer insulating film 98 are sequentially laminated so as to cover the capacitor contact pad 96. The interlayer insulating film 98 is formed to a thickness of 1000 nm to 1500 nm.

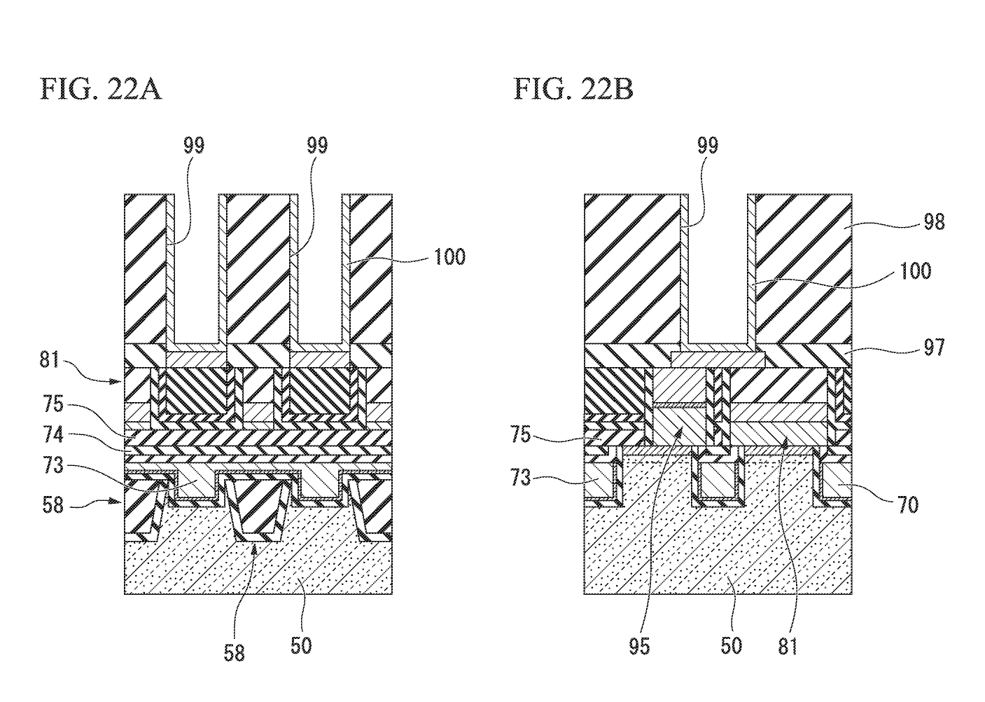

As shown in FIG. 22A and FIG. 22B, a deep hole 99 that penetrates the third interlayer insulating film 98 and the stopper film 97 is formed. The upper surface of the capacitor contact pad 96 is shown through the deep hole 99. A lower electrode (first electrode) 100 of a capacitor 103 is formed so as to cover the inner wall of the deep hole 99. The bottom part of the lower electrode 100 is connected to the capacitor contact pad 96. The lower electrode 100 may include, but is not limited to, titanium nitride or the like. For example, because the above-described interlayer insulating film 98 with a thickness of 1000 nm to 1500 nm is formed, the depth of the deep hole 99 is also 1000 nm to 1500 nm. The width (diameter) of the deep hole 99 is made 50 nm. The aspect ratio (depth/width) of the deep hole 99 is therefore 20 to 30. The present embodiment achieves apertures (deep holes) having such large aspect ratios. In the case in which the width of the deep hole 99 is 40 nm, the thickness of the interlayer insulating film 98 is formed to be 800 nm to 1200 nm. If the aspect ratio is smaller than 20, it becomes difficult to obtain capacitance of the capacitor required for a semiconductor memory device. If the aspect ratio exceeds 30, the etching process of the deep hole using anisotropic dry etching is difficult.

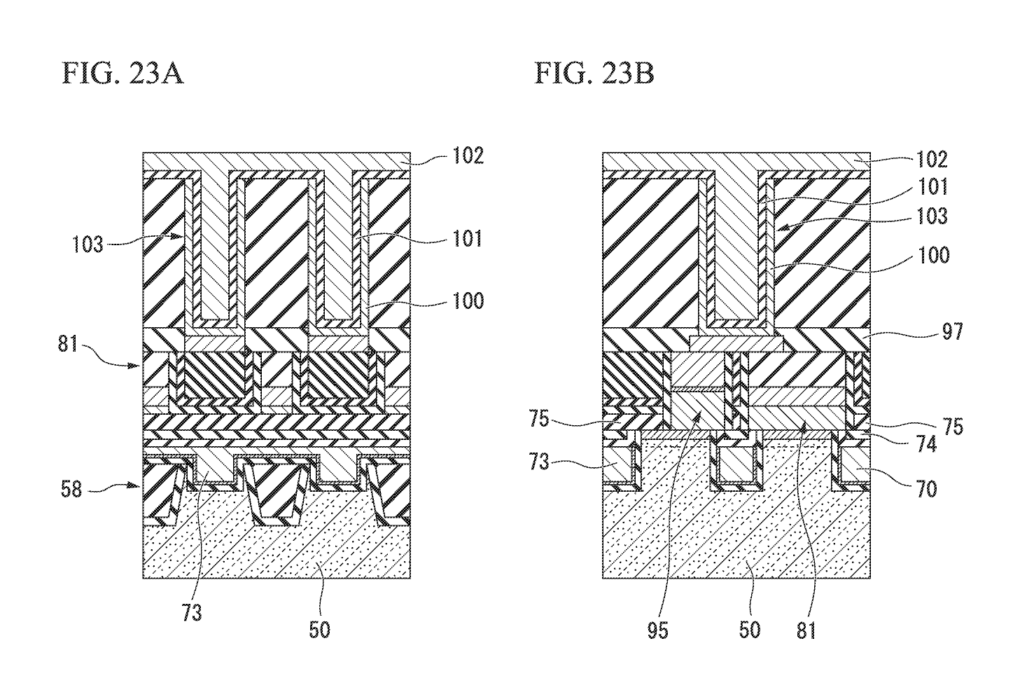

As shown in FIG. 23A and FIG. 23B, a capacitor 103 is formed. The process to form the capacitor 103 generally includes the following steps. The first electrode 100 is formed. A capacitive insulating film 101 that contains at least two types of metal elements is formed so as to cover the surface of the first electrode 100. The upper electrode (second electrode) 102 which may include, but is not limited to, titanium nitride or the like is formed so as to cover the capacitive insulating film 101.

Forming the capacitive insulating film 101 is performs under the condition at which covering characteristics of each of the precursors that contain the metal elements are substantially the same. According to the present embodiment, the covering characteristic means a ratio of covering the first electrode 100, that is, the bottom of the deep hole 99 with a precursor per time of supplying the precursor. That is, according to the present embodiment, the capacitive insulating film 101 is formed by ALD in which each of the precursors is supplied to the vicinity of the semiconductor substrate surface at substantially the same timing. In this case, the capacitive insulating film 101 is formed using supplying conditions adjusted so that the dependency of the ratio of covering the surface of the first electrode 100 on the precursor supplying time is substantially the same. Also, according to the present embodiment, the capacitive insulating film 101 is formed by ALD in which a period of time of supplying a first precursor, which may be an aluminum precursor, may overlap a period time of supplying a second precursor, which may be zirconium precursor.

Forming the capacitive insulating film 101 using ALD will be described below in detail.

In this case, the method of forming an ALD film made of a ZrAlO film will be described as an example.

TMA is used as the aluminum precursor, and TEMAZ is used as the zirconium precursor.

After setting the semiconductor substrate 50 over which the lower electrode 100 is formed into the reaction chamber of an ALD film depositing apparatus, the reaction chamber is first vacuum exhausted. Then, the semiconductor substrate 50 is preheated to stabilize the temperature thereof to 220° C. The ALD film deposition apparatus includes a reaction chamber that can perform film deposition of a metal compound film by ALD and a gas supplying system capable of introducing an oxidant and raw gases (precursors).

### (First ALD Flow Sequence)

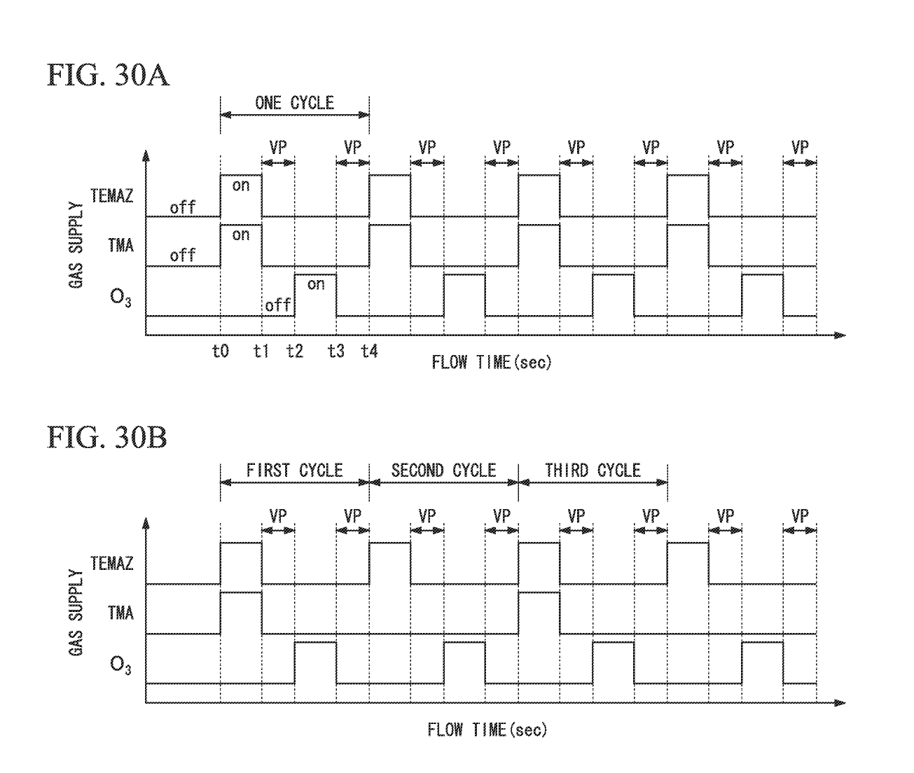

Each step is performed based on a first ALD flow sequence as shown in FIG. 30A under the condition of a stable temperature.

(1) First, a step of supplying precursors at substantially the same timing is performed. At time t0, TMA that serves as the aluminum precursor and TEMAZ that serves as the zirconium precursor are supplied at substantially the same timing. In this case, the supply amount of each precursor is set at conditions in which the covering characteristics are made to be substantially the same. Namely, TMA and TEMAZ are supplied to the reaction chamber so that the supply amount of the TEMAZ with respect to the supply amount of the TMA is within the range from 2.5 to 3.5 times, and preferably 3 times.

According to the present embodiment, the TMA supply amount is 0.2 slm, and the TEMAZ supply amount is 0.6 slm. Although the flow amounts of each precursor carrier gas are adjustable within the range from 1 to 5 slm, in this case the amounts were each 2 slm. The overall pressure in the reaction chamber was 100 Pa. As described above, the flow amounts of each of the carrier gases and the total pressure in the reaction chamber do not influence the covering characteristics of the TMA and TEMAZ. Supplying time of the TMA and the TEMAZ is 30 seconds. As shown in FIG. 29A, although, under the above supplying conditions, when the precursor supplying time is 10 seconds, the TMA and TEMAZ covering ratios are both 100%, the present embodiment makes this 30 seconds, in consideration of a sufficient margin. By doing this, a mono-molecular adsorption layer with a mixture of TMA and TEMAZ is formed over the entire surface of the semiconductor substrate, including the surface of the first electrode 100. A first molecular ratio of TEMAZ in the mono-molecular layer at a bottom of the deep hole 99 is substantially the same as a second molecular ratio of TEMAZ in the mono-molecular layer over a top surface of the interlayer insulating film 98.

(2) A step of exhausting the precursors (vacuum purge step VP) is performed. At t1, at which 30 seconds of supplying precursors at substantially the same timing has elapsed, as the supply of TMA and TEMAZ is stopped and the reaction chamber is vacuum exhausted, nitrogen gas is supplied, and the precursors (TMA and TEMAZ) which remain within the reaction chamber are purged. The step of exhausting the precursors is performed for 10 seconds.

(3) A step of supplying an oxidant (ozone: O₃) is performed. At t2, at which 10 seconds of exhausting the precursors has elapsed, ozone is supplied at 1 slm for 30 seconds. Pressure in the reaction chamber is 150 Pa. By doing this, TMA and TEMAZ, which have been already adsorbed onto the surface of semiconductor substrate, are oxidized, and a mono-molecule ZrAlO layer, in which AlO and ZrO are mixed, is formed.

(4) A step of exhausting the oxidant (vacuuming purge step VP) is performed. At the t3, at which an ozone supplying time has passed for 30 s, while supplying the ozone is stopped and the reaction chamber is also vacuumed, nitrogen gas being supplied and the ozone which has remained within the reaction chamber being purged. The time is 10 seconds.

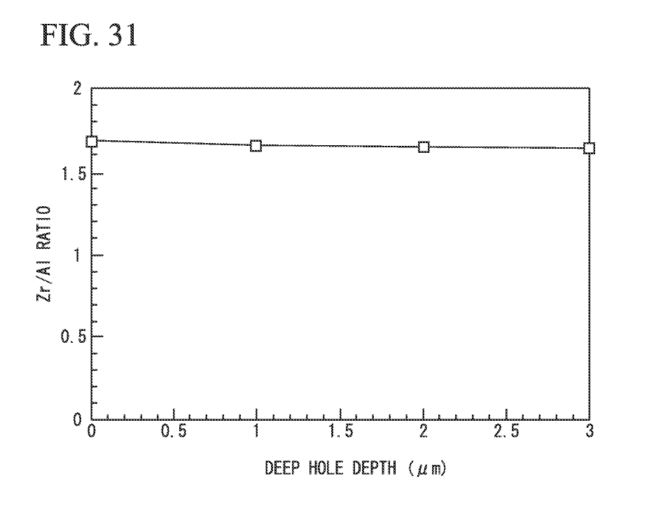

With the above-noted (1) to (4) steps as a first basic cycle, the cycle is repeated until depositing the ZrAlO film that reaches the desired film thickness. As an example, a sample of a ZrAlO film with a thickness of 10 nm was made in a deep hole. The zirconium/aluminum ratio (atomic ratio) in the ZrAlO film was investigated using TEM-EDX. The results are shown in FIG. 31. It was confirmed that the zirconium/aluminum ratio up to the position at a depth of 3 μm of the deep hole was constantly 1.7. The zirconium/aluminum ratio in the depth direction of the deep hole is substantially the same. It was confirmed that the ZrAlO film having substantially uniform composition was formed within the deep hole. That is, it is possible to form a ZrAlO film under conditions at which the zirconium/aluminum ratio of the formed ZrAlO film in the depth direction of the deep hole is held constant by forming a film using the ALD film formation method that makes the covering characteristics of each precursor the same. At this time, TMA and TEMAZ, which serve as precursors, are supplied at substantially the same timing. Therefore, it is possible to suppress variations of the leakage current of the capacitor and variations of the dielectric constant of the capacitive insulating film caused by a difference in composition.

Under the above-described conditions, the film formation rate is 0.125 nm/cycle, and if the first basic cycle is repeated at 48 times, a ZrAlO film with the thickness of 6 nm can be formed.

### (Second ALS Flow Sequence)

FIG. 30B is a second ALD flow sequence that inserts a second cycle supplying only TEMAZ between the first cycle and a third cycle in which TMA and TEMAZ are supplied at substantially the same timing, as described the first ALD flow sequence. That is, the first basic cycle in which the TMA and TEMAZ are supplied at the substantially the same timing and the second basic cycle in which only the TEMAZ is supplied are combined as the third basic cycle will be explained. The third basic cycle is repeated until the desired ZrAlO film thickness. The third cycle is the same as the first basic cycle. The first basic cycle has the same conditions as in the above-described first ALD flow sequence. The second basic cycle can be performed by setting so as not to supply TMA in the first ALD flow sequence. In FIG. 30B, although the example of the second basic cycle is performed only one time is described, but is not limited thereto. After repeatedly performing the second basic cycle, the third cycle can be performed. By such an ALD flow sequence, it is possible to control the aluminum concentration in the ZrAlO film down to a sufficiently low value while holding the zirconium/aluminum ratio in the ZrAlO film constant in the depth direction of the deep hole.

For example, as shown in FIG. 31, in the case in which the ZrAlO film is formed using the first ALD flow sequence the zirconium/aluminum ratio is 1.7. This indicates that ZrO accounts for 63% of the entire ZrAlO film that is formed, and that AlO accounts for 37%.

The second ALD flow sequence as shown in FIG. 30B repeats the first basic cycle and the second cycle each one time. The first basic cycle forms 37% of AlO and 63% of ZrO, and the second basic cycle forms 100% of ZrO. Therefore, the AlO within the formed ZrAlO film is 37/200, or 18.5%. For example, the second ALD flow sequence performs the first basic cycle one time, and then performs the second basic cycle 4 times continuously without supplying TMA. This combination constitutes the third basic cycle, thereby forming a ZrAlO film. In this case, the ratio of AlO is only 37% that is formed in the first cycle, and in the second basic cycle of 4 times the ratio of ZrO is 100%. Therefore, the AlO of the entire ZrAlO film becomes 37/500, or 7.4%. In the same manner, in the third basic cycle that performs the second basic cycle 6 times continuously, the ratio of AlO of the entire ZrAlO film is 5.3%. In the third basic cycle that performs the second basic cycle 7 times continuously, the ratio of AlO of the entire ZrAlO film is 4.6%.

In order to form the ZrAlO film with a thickness of 6 nm in which the ratio of AlO is 5% using the second ALD flow sequence, a repetition made of one time of the first basic cycle and then the second basic cycle for 6 times continuously constitutes the third basic cycle, and the third basic cycle can be repeated 7 times. In this case, the film thickness of the ZrAlO film is 6.1 nm.

As shown in FIG. 34B as the related art, with an ALD flow sequence of alternate laminations of AlO and ZrO, it is only possible to form one or so film of AlO in order to make the ratio of AlO within the ZrAlO film approximately 5%, resulting in extremely poor controllability. However, if the second ALD flow sequence according to the present embodiment is used, in order to make the ratio of AlO 5%, a supplying cycle in which TMA and TEMAZ are supplied at the same timing may be introduced at a rate of one time out of 7 times or one time out of 8 times. By doing this, it is possible to improve the controllability while the zirconium/aluminum ratio is substantially uniform within the deep hole, and also to improve the productivity.

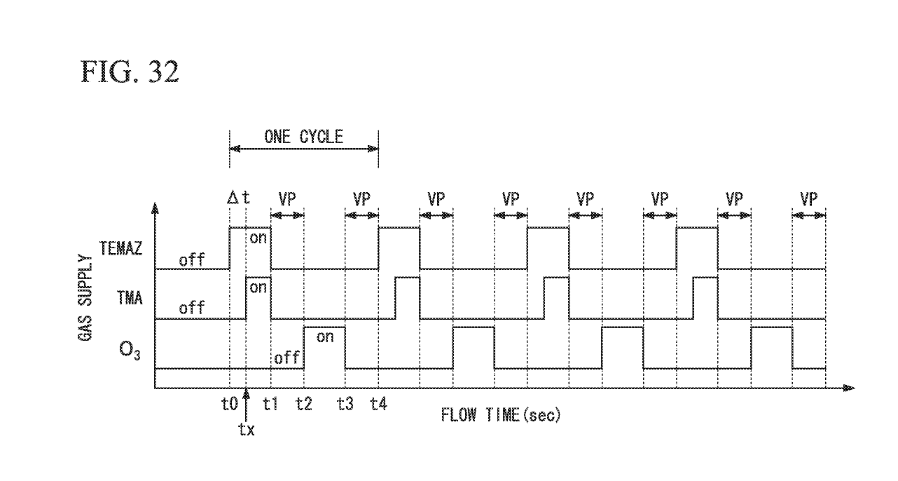

FIG. 32 shows the third ALD flow sequence, in which a changed first ALD flow sequence as shown in FIG. 30A is used. That is, in the step of supplying the TMA and TEMAZ at the substantially the same timing, instead of the supplying the TMA and TEMAZ at the substantially the same timing at the time tO0, supplying TMA is started from a time tx that is somewhat later than t0. After the start of supplying TEMAZ first, the supplying of TMA is made to start later. Namely, the period of time of supplying TMA is started during the period of time of supplying TEMAZ. The times of the end of supplying are both made the same, t1. The supplying start time delay time Δt is 1 second to 5 seconds. In this manner, by setting the delay Δt in the TMA supplying time in the supplying step, the concentration of AlO can be further reduced compared with the first ALD flow sequence in FIG. 30A. A combination of the second ALD flow sequence in FIG. 30B and the third ALD flow sequence in FIG. 32 can perform better control, so as to make the amount of AlO contained within the ZrAlO film a low concentration.

According to the result of experimentation by the inventor, it was demonstrated that the concentration of AlO within the ZrAlO film that achieves a reduction of the leakage current and an improvement in the dielectric constant of the ZrAlO film is the range between 3 to 6%, and preferably between 4 to 5%. In the case of lower than 3%, the leakage current increases, and in the case of greater than 6%, the dielectric constant decreases, and a large capacitance in the capacitor cannot be obtained.

By using the above-described second ALD flow sequence or the combination of the second ALD flow sequence and the third ALD flow sequence, it is possible to maintain the AlO concentration within the ZrAlO film within the range of 3 to 6%.

Returning to the description of FIG. 23, the upper electrode (second electrode) 102 is formed so as to cover the capacitive insulating film 101, thereby forming the capacitor 103.

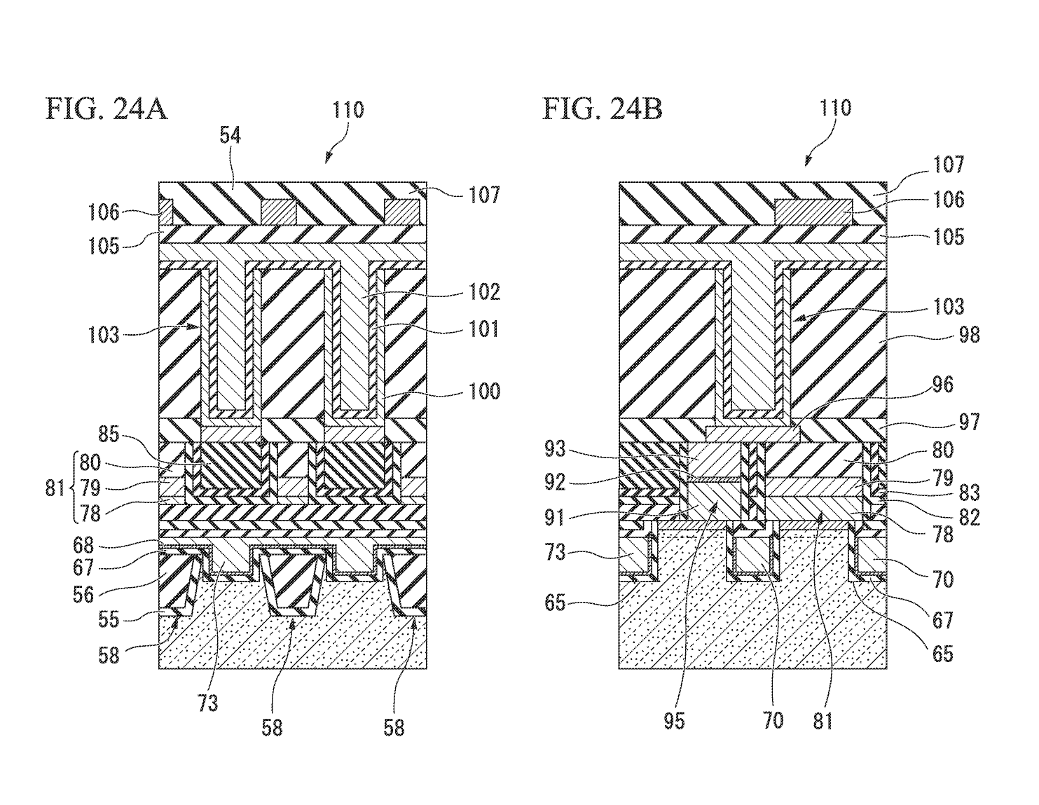

As shown in FIG. 24A, and FIG. 24B, after forming the fourth interlayer insulating film 105 which may be, but is not limited to, a silicon oxide film or the like so as to cover the upper electrode 102, the upper metal wiring 106 is formed. The upper metal wiring 106 may include, but is not limited to, aluminum (Al), copper (Cu) or the like. After doing this, the surface protective film 107 is formed, thereby completing the semiconductor memory device 110 that has the same structure as that of the semiconductor memory device (DRAM) 1 as shown in FIG. 1 and FIG. 2.

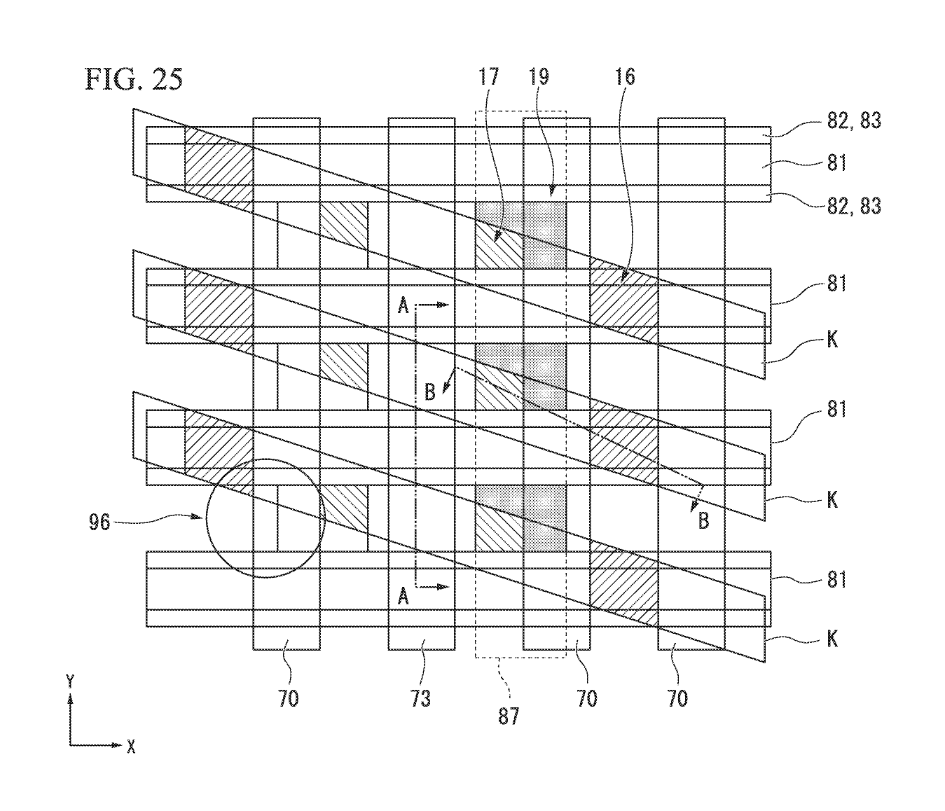

FIG. 25 shows a planar structure of the wiring structure of the semiconductor memory device 110 obtained by the above-described formation method. In the wiring structure shown in FIG. 25 shows insulating films 82 and liner films 83 at the both sides of bit wiring 81 that is omitted from the description in the wiring structure shown in FIG. 1.

According to the method for forming the semiconductor memory device 110 of the present embodiment, a plurality of the precursors are supplied at the same timing under the condition at which covering characteristics of each of the precursors that contain the metal elements are substantially the same. That is, the plurality of the precursors are supplied at the same timing under the condition where the covering characteristics of the precursors are adjusted so as to be substantially the same. Also, the relationship between the flow amounts of each source gas and the saturation time of film thickness per one cycle is determined beforehand and the time required for each ALD film thickness to saturate is adjusted to so as to be constant. Each source gas is supplied at the substantially same timing to the vicinity of the first electrode 100 with a flow amount in which the film thickness saturation time of each of the ALD film is the same and with longer time than the film thickness saturation time. Thereby, it is possible to supply a sufficient amount of each gas for each ALD film growth to the entire first electrode at the substantially same timing. For this reason, even in a three-dimensional structure in which the first electrode 100 has a trench (deep hole), it is possible to make the time until in which each source gas is sufficiently supplied to the bottom part of the deep hole of the first electrode 100 (film saturation time) equal. Therefore, it is possible to form a capacitive insulating film made of an ALD film having a substantially uniform composition, over the bottom part and other overall regions of the deep hole of the first electrode. As a result, it is possible to control the occurrence of leakage current, and to form a semiconductor memory device having better refresh characteristics with respect to that in the related art.

For this reason, the capacitive insulating film 101 made of ALD film having a substantially uniform composition ratio of the metal elements can be formed over the entire surface of the first electrode 100.

Also, because the source gases are supplied at the substantially the same timing and with flow amounts that make the thickness saturation times for each ALD film the same, it is not necessary to establish the overall source gas supplying time to adjust to the source gas having the longest film thickness saturation time. For this reason, it is possible to shorten the source gas supplying time when forming an ALD film using a plurality of source gases. For this reason, it is possible to form an ALD film having a substantially uniform composition onto the first electrode 100 of a three-dimensional structure in a short time. For this reason, it is possible to shorten the formation step of the semiconductor memory device 1.

### Second Embodiment

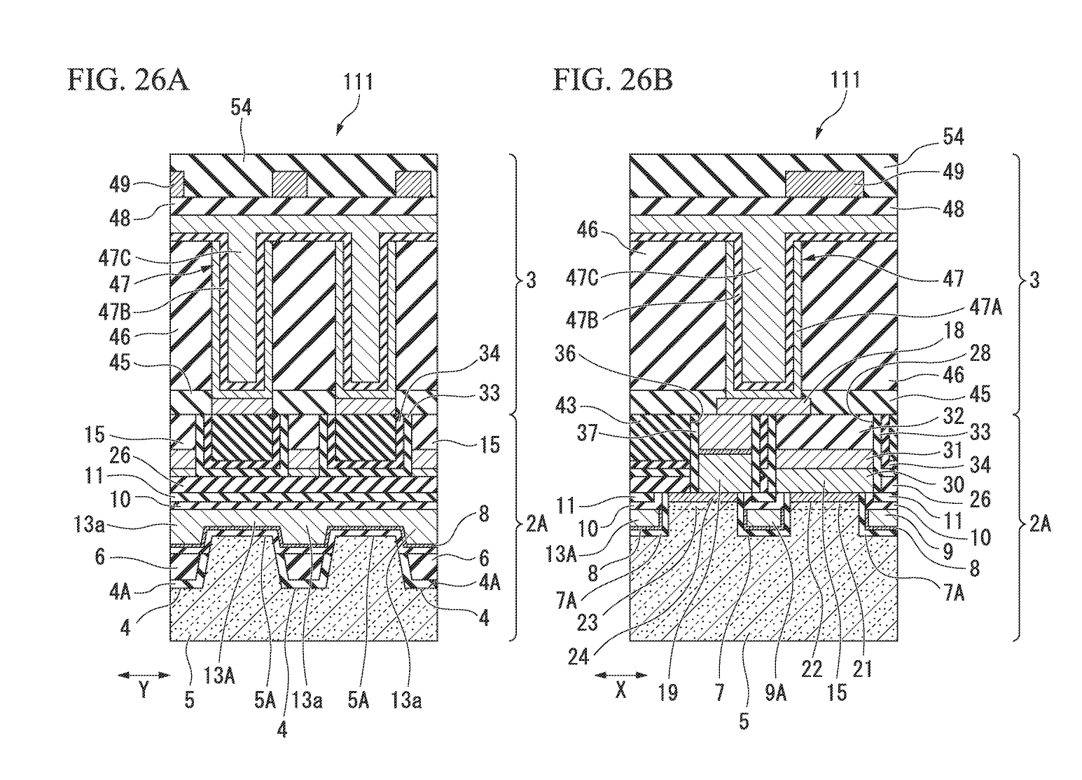

An example of a semiconductor memory device 111 having a saddle-fin-type cell transistor instead of the semiconductor memory device 1 having a recess channel type cell transistor described above as shown in FIGS. 1, 2A and 2B will be described in FIG. 26A and FIG. 26B. The semiconductor memory device 111 is different from the semiconductor memory device 1 with respect to the part of the cell transistor. The other parts thereof have the same structure as the semiconductor memory device 1. Because these have been described, structures that are the same as structures in the semiconductor memory device 1 which has been described will be omitted in the detailed description.

FIG. 26A is a fragmentary cross sectional elevation view, at a position equivalent to the position along the line A-A′ of FIG. 1, illustrating a semiconductor device including a memory cell in accordance with a second preferred embodiment of the present invention. FIG. 26B is a fragmentary cross sectional elevation view, at a position equivalent to the position along the line B-B′ of FIG. 1, illustrating the semiconductor device including the memory cell in accordance with the second preferred embodiment of the present invention. The semiconductor memory device 111 of the present embodiment is generally constituted by a transistor formation region 2A and a capacitor formation region 3 as shown in cross-sectional view of FIG. 26A and FIG. 26B.

The semiconductor memory device 111 of the present embodiment has a different cell transistor structure from that of the semiconductor memory device 1 described above. The semiconductor device 111 includes a buried wiring 13a including an electrode 13a which is formed in an upper portion of the element separation trench 4. The electrode 13a is thicker than the buried wirings 13a. The protrusion 5A of the surface region of the semiconductor substrate 5 which locates between the adjacent electrodes 13a in the Y direction of the FIG. 26A is formed to served as a channel region.

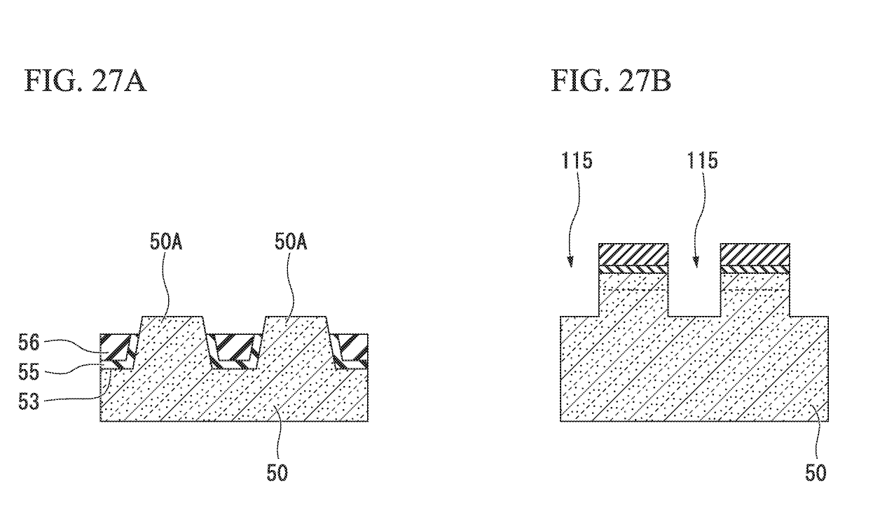

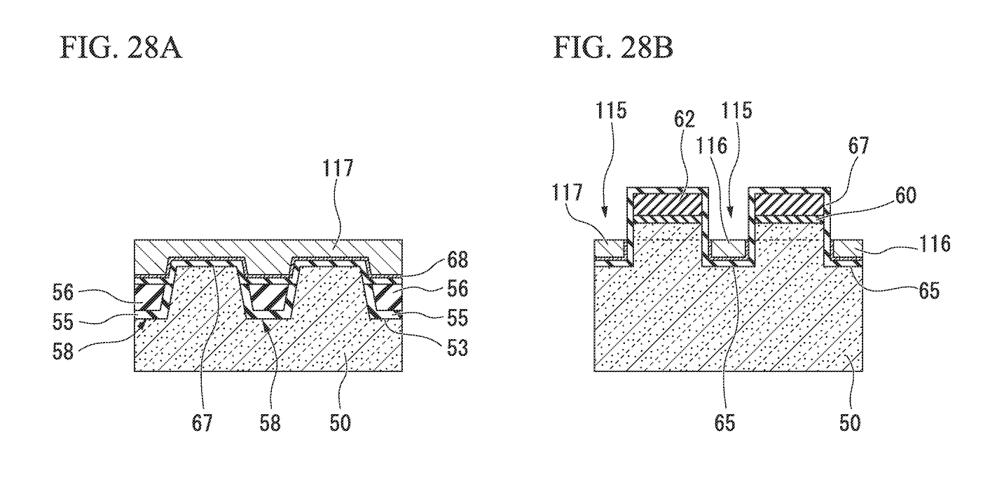

A method for forming the semiconductor memory device 111 will be described. FIG. 27A, FIG. 27B, FIG. 28A and FIG. 28B are fragmentary cross sectional elevation views illustrating the semiconductor device in a step involved in the method of forming the semiconductor device of FIGS. 26A and 26B in accordance with the second preferred embodiment of the present invention.

The method for forming the semiconductor memory device 111 of the present embodiment follows the description based on FIGS. 3A to 7B in the same manner as with the semiconductor memory device 1 of the above-described embodiment. As such, and as shown in shown in FIGS. 7A and 7B, a silicon nitride film 62 for use as a mask, and a carbon film (amorphous carbon film) 63 are sequentially deposited over the semiconductor substrate 50 and are patterned for the formation of a gate electrode trench. Then, as shown in FIG. 27A and FIG. 27B, the semiconductor substrate 50 is dry etched so as to form trenches (gate electrode trenches) 115. These trenches 115 are formed as linear patterns that extend in a prescribed direction (Y direction in FIG. 1) that is perpendicular with respect to the active regions K, in the same manner as in the above-described embodiment.

When the etching process is performed, in contrast to the first embodiment as shown in FIGS. 8A and 8B, in which the semiconductor substrate 5 is etched more deeply than the isolation trench region 65, in the present embodiment in reverse, the part of the isolation trench 53 is etched more deeply than the trench 115 of the semiconductor substrate 50, thereby enabling formation of a protrusion 50A in the semiconductor substrate 50 and enabling the protrusion 50A to be made a cell transistor channel region.

After that, in the same manner as described in the step in FIGS. 9A and 9B of the first embodiment, the gate insulating film 67, the titanium nitride film 68 and the tungsten film 69 are deposited and the etching back process is performed, thereby enabling formation of a buried word line 116 and a buried wiring 116 within a trench (gate electrode trench) 115, as shown in FIG. 28A and FIG. 28B. Next, in the same manner as with the first embodiment, the steps after FIGS. 11A and 11B are sequentially performed after the condition of FIG. 28A and FIG. 28B, thereby forming the semiconductor memory device 111 having a cross-sectional structure as shown in FIG. 26A and FIG. 26B.

The method for forming the semiconductor memory device 111 having the saddle-fin-type cell transistor of the present embodiment is different from the method for forming the semiconductor memory device 1 of the first embodiment with regard to the point of part of the isolation trench 53 being etched more deeply than the trench 115 of the semiconductor substrate 50. The remaining parts are the same as for the semiconductor memory device 1 that is described in the first embodiment, and the same effect can be achieved.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device which includes hardware and/or software that is constructed and/or programmed to carry out the desired function.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method for forming a semiconductor device, the method comprising:
forming an insulating film over a semiconductor substrate;
forming a hole in the insulating film; and
forming a film including ZrAlO over the insulating film and in the hole,
wherein forming the film including ZrAlO comprises:
supplying a first precursor including zirconium and a second precursor including aluminum into a reaction chamber at a supply amount ratio of the first precursor to the second precursor in the range from 2.5 to 3.5;
exhausting the first precursor and the second precursor from the reaction chamber;
supplying an oxidant into the reaction chamber to oxidize zirconium and aluminum; and
exhausting the oxidant from the reaction chamber.

2. The method according to claim 1, wherein the first precursor and the second precursor are supplied to the reaction chamber at substantially the same timing.

3. The method according to claim 1, wherein a first period of time of supplying the first precursor at least partially overlaps a second period of time of supplying the second precursor.

4. The method according to claim 3, wherein the second period of time is started during the first period of time.

5. The method according to claim 3, wherein supplying the first precursor and supplying the second precursor are finished at substantially the same timing.

6. The method according to claim 1, wherein forming the film including ZrAlO further comprises repeating a first cycle, and
the first cycle includes:
supplying the first precursor and the second precursor;
exhausting the first precursor and the second precursor;
supplying the oxidant; and
exhausting the oxidant.

7. The method according to claim 6, wherein forming the film including ZrAlO further comprises: a second cycle between the first cycles, and
the second cycle includes:
supplying the first precursor into the reaction chamber;
exhausting the first precursor from the reaction chamber;
supplying the oxidant into the reaction chamber to oxidize zirconium; and
exhausting the oxidant from the reaction chamber.

8. The method according to claim 7, wherein the number of performing the first cycle is less than the number of performing the second cycle.

9. The method according to claim 1, wherein the first precursor is tetrakis(ethylmethylamino)zirconium and the second precursor is trimethylaluminum.

10. A method for forming a semiconductor device, the method comprising:
forming an insulating film over a semiconductor substrate;
forming a hole in the insulating film;
forming a conductive film over the insulating film and in the hole; and
forming a film including ZrAlO over the conductive film by atomic layer deposition,
wherein forming the film including ZrAlO comprises:
supplying a first precursor including zirconium and a second precursor including aluminum into a reaction chamber to form a mono-molecular layer so that a first molecular ratio of the first precursor in the mono-molecular layer at a bottom of the hole is substantially the same as a second molecular ratio of the first precursor in the mono-molecular layer over a top surface of the insulating film;
exhausting the first precursor and the second precursor from the reaction chamber;
supplying an oxidant to the reaction chamber to oxidize zirconium and aluminum; and
exhausting the oxidant from the reaction chamber.

11. The method according to claim 10, wherein the first precursor and the second precursor are supplied to the reaction chamber at substantially the same timing.

12. The method according to claim 10, wherein a first period of time of supplying the first precursor at least partially overlaps a second period of time of supplying the second precursor.

13. The method according to claim 12, wherein the second period of time is started during the first period of time.

14. The method according to claim 12, wherein supplying the first precursor and supplying the second precursor are finished at substantially the same timing.

15. The method according to claim 10, wherein forming the film including ZrAlO further comprises repeating a first cycle, and
the first cycle includes:
supplying the first precursor and the second precursor;
exhausting the first precursor and the second precursor;
supplying the oxidant; and
exhausting the oxidant.

16. The method according to claim 15, wherein forming the film including ZrAlO further comprises: a second cycle between the first cycles, and
the second cycle includes:
supplying the first precursor into the reaction chamber;
exhausting the first precursor from the reaction chamber;
supplying the oxidant to the reaction chamber to oxidize zirconium; and
exhausting the oxidant from the reaction chamber.

17. The method according to claim 16, wherein the number of performing the first cycle is less than the number of performing the second cycle.

18. The method according to claim 10, wherein the first precursor is tetrakis(ethylmethylamino)zirconium and the second precursor is trimethylaluminum.

19. A method for forming a semiconductor device, the method comprising:
forming an insulating film over a semiconductor substrate;
forming a hole in the insulating film;
forming a first electrode in the hole;
forming a capacitive insulating film including ZrAlO over the conductive film and the insulating film; and
forming a second electrode over the capacitive insulating film,
wherein forming the capacitive insulating film comprises:
supplying a first precursor including zirconium and a second precursor including aluminum into a reaction chamber at a supply amount ratio of the first precursor to the second precursor in the range from 2.5 to 3.5;
exhausting the first precursor and the second precursor from the reaction chamber;
supplying an oxidant into the reaction chamber to oxidize zirconium and aluminum; and
exhausting the oxidant from the reaction chamber.

20. The method according to claim 19, wherein forming the hole comprises:
forming the hole in the insulating film so that an aspect ratio of the hole is from 20 to 30.
